(19) United States
(12) Patent Application Publication
(10) Pub. No.: US 2021/0296618 A1
(43) Pub. Date: Sep. 23, 2021

(54) PEROVSKITE LIGHT EMITTING DEVICE WITH MULTIPLE EMISSIVE LAYERS

(71) Applicant: PEROLED LIMITED, Sedgefield (GB)

(72) Inventor: Peter LEVERMORE, Sedgefield (GB)

(21) Appl. No.: 17/264,336

(22) PCT Filed: Jul. 29, 2019
(86) PCT No.: PCT/GB2019/052114

§ 371 Date: Jan. 29, 2021

(30) Foreign Application Priority Data
Jul. 30, 2018 (GB) 1812402.4

(51) Int. Cl. H01L 51/52; C09K 11/66; C01G 21/16; C07F 7/24; H01L 51/00

(52) U.S. Cl. CPC H01L 51/5278; C09K 11/665; H01L 51/502; C07F 7/24; H01L 51/0037; C01G 21/16

(57) ABSTRACT

A light emitting device is provided. The device comprises a first electrode, a second electrode and at least two emissive layers. A first emissive layer of the at least two emissive layers is disposed over the first electrode. A second emissive layer of the at least two emissive layers is disposed over the first emissive layer. The first emissive layer is in contact with the second emissive layer. The second electrode is disposed over the second emissive layer. At least one emissive layer of the at least two emissive layers comprises a perovskite light emitting material. The device comprises at least one further emissive layer of the at least two emissive layers, wherein the at least one further emissive layer comprises a perovskite light emitting material, an organic light emitting material or a quantum dot light emitting material.

### TECHNICAL FIELD

The present invention relates to light emitting devices, and in particular to light emitting devices that comprise one or more perovskite light emitting materials and two or more emissive layers for application in devices, such as displays, light panels and other devices including the same.

### BACKGROUND

Perovskite materials are becoming increasingly attractive for application in optoelectronic devices. Many of the perovskite materials used to make such devices are earth-abundant and relatively inexpensive, so perovskite optoelectronic devices have the potential for cost advantages over alternative organic and inorganic devices. Additionally, inherent properties or perovskite materials, such as an optical band gap that is readily tunable across the visible, ultra-violet and infra-red, render them well suited for optoelectronics applications, such as perovskite light emitting diodes (PeLEDs), perovskite solar cells and photodetectors, perovskite lasers, perovskite transistors, perovskite visible light communication (VLC) devices and others. PeLEDs comprising perovskite light emitting material may have performance advantages over conventional organic light emitting diodes (OLEDs) and quantum dot light emitting diodes (QLEDs), respectively comprising organic light emitting material and quantum dot light emitting material. For example, strong electroluminescent properties, including unrivalled high colour purity enabling displays with wider colour gamut, excellent charge transport properties and low non-radiative rates.

PeLEDs make use of thin perovskite films that emit light when voltage is applied. PeLEDs are becoming an increasingly attractive technology for use in applications such as displays, lighting and signage. As an overview, several PeLED materials and configurations are described in Adjokatse et al., which is included herein by reference in its entirety.

One potential application for perovskite light-emitting materials is a display. Industry standards for a full-colour display require for sub-pixels to be engineered to emit specific colours, referred to as “saturated” colours. These standards call for saturated red, green and blue sub-pixels, where colour may be measured using CIE 1931 (x, y) chromaticity coordinates, which are well known in the art. One example of a perovskite material that emits red light is methylammonium lead iodide (CH₃NH₃PbI₃). One example of a perovskite material that emits green light is formamidinium lead bromide (CH(NH₂)₂PbBr₃). One example of a perovskite material that emits blue light is methylammonium lead chloride (CH₃NH₃PbCl₃). In a display, performance advantages, such as increased colour gamut, may be achieved where PeLEDs are used in place of or in combination with OLEDs and/or QLEDs. In the present invention, performance advantages are demonstrated by including one or more perovskite light emitting materials in light emitting devices with multiple emissive layers. The demonstrated light emitting device is particularly well-suited to generating white light emission for application in displays and/or light panels.

As used herein, the term “perovskite” includes any perovskite material that may be used in an optoelectronic device. Any material that may adopt a three-dimensional (3D) structure of ABX₃, where A and B are cations and X is an anion, may be considered a perovskite material. FIG. 3 depicts an example of a perovskite material with a 3D structure of ABX₃. The A cations may be larger than the B cations. The B cations may be in 6-fold coordination with surrounding X anions. The A anions may be in 12-fold coordination with surrounding X anions.

There are many classes of perovskite material. One class of perovskite material that has shown particular promise for optoelectronic devices is the metal halide perovskite material class. For metal halide perovskite material, the A component may be a monovalent organic cation, such as methylammonium (CH₃NH₃⁺) or formamidinium (CH(NH₂)₂⁺), an inorganic atomic cation, such as caesium (Cs⁺), or a combination thereof, the B component may be a divalent metal cation, such as lead (Pb⁺), tin (Sn⁺), copper (Cu⁺), europium (Eu⁺) or a combination thereof, and the X component may be a halide anion, such as I⁻, Br⁻, Cl⁻, or a combination thereof. Where the A component is an organic cation, the perovskite material may be defined as an organic metal halide perovskite material. CH₃NH₃PbBr₃ and CH(NH₂)₂PbI₃ are non-limiting examples of metal halide perovskite materials with a 3D structure. Where the A component is an inorganic cation, the perovskite material may be defined as an inorganic metal halide perovskite material. CsPbI₃, CsPbCl₃ and CsPbBr₃ are non-limiting examples of inorganic metal halide perovskite materials.

As used herein, the term “perovskite” further includes any material that may adopt a layered structure of L₂(ABX₃)ₙ₋₁BX₄ (which may also be written as L₂Aₙ₋₁BₙX₃ₙ₊₁), where L, A and B are cations, X is an anion, and n is the number of BX₄ monolayers disposed between two layers of cation L. FIG. 4 depicts examples of perovskite materials with a layered structure of L₂(ABX₃)ₙ₋₁BX₄ having different values for n. For metal halide perovskite material, the A component may be a monovalent organic cation, such as methylammonium (CH₃NH₃⁺) or formamidinium (CH(NH₂)₂⁺), an atomic cation, such as caesium (Cs⁺), or a combination thereof, the L component may be an organic cation such as 2-phenylethylammonium (C₆H₅C₂H₄NH₃⁺) or 1-napthylmethylammonium (C₁₀H₇CH₂NH₃⁺), the B component may be a divalent metal cation, such as lead (Pb⁺), tin (Sn⁺), copper (Cu⁺), europium (Eu⁺) or a combination thereof, and the X component may be a halide anion, such as I⁻, Br⁻, Cl⁻, or a combination thereof. (C₆H₅C₂H₄NH₃)₂(CH(NH₂)₂PbBr₃)ₙ₋₁PbBr₄ and (C₁₀H₇CH₂NH₃)₂(CH₃NH₃PbI₂Br)ₙ₋₁PbI₃Br are non-limiting examples of metal halide perovskite material with a layered structure.

Where the number of layers n is large, for example n greater than approximately 10, perovskite material with a layered structure of L₂(ABX₃)ₙ₋₁BX₄ adopts a structure that is approximately equivalent to perovskite material with a 3D structure of ABX₃. As used herein, and as would generally be understood by one skilled in the art, perovskite material having a large number of layers may be referred to as a 3D perovskite material, even though it is recognized that such perovskite material has reduced dimensionality from n=∞. Where the number of layers n=1, perovskite material with a layered structure of L₂(ABX₃)ₙ₋₁BX₄ adopts a two-dimensional (2D) structure of L₂BX₄. Perovskite material having a single layer may be referred to as a 2D perovskite material. Where n is small, for example n in the range of approximately 2-10, perovskite material with a layered structure of L₂(ABX₃)ₙ₋₁BX₄ adopts a quasi-two-dimensional (Quasi-2D) structure. Perovskite material having a small number of layers may be referred to as a Quasi-2D perovskite material. Owing to quantum confinement effects, the energy band gap is lowest for layered perovskite material structures where n is highest.

Perovskite material may have any number of layers. Perovskites may comprise 2D perovskite material, Quasi-2D perovskite material, 3D perovskite material or a combination thereof. For example, perovskites may comprise an ensemble of layered perovskite materials having different numbers of layers. For example, perovskites may comprise an ensemble of Quasi-2D perovskite materials having different numbers of layers.

As used herein, the term “perovskite” further includes films of perovskite material. Films of perovskite material may be crystalline, polycrystalline or a combination thereof, with any number of layers and any range of grain or crystal size.

As used herein, the term “perovskite” further includes nanocrystals of perovskite material that have structure equivalent to or resembling the 3D perovskite structure of ABX₃ or the more general layered perovskite structure of L₂(ABX₃)ₙ₋₁BX₄. Nanocrystals of perovskite material may include perovskite nanoparticles, perovskite nanowires, perovskite nanoplatelets, or a combination thereof. Nanocrystals of perovskite material may be of any shape or size, with any number of layers and any range of grain or crystal sizes. FIG. 5 depicts an example of nanocrystal of perovskite material with a layered structure that resembles L₂(ABX₃)ₙ₋₁BX₄, where n=5 and L cations are arranged at the surface of the perovskite nanocrystal. The term “resembles” is used because for a nanocrystal of perovskite material, the distribution of L cations may differ from that of perovskite material with a formal layered structure of L₂(ABX₃)ₙ₋₁BX₄. For example, in a nanocrystal of perovskite material, there may be a greater proportion of L cations arranged along the sides of the nanocrystal.

Several types of perovskite material may be stimulated to emit light in response to optical or electrical excitation. That is to say that perovskite light emitting material may be photoluminescent or electroluminescent. As used herein, the term “perovskite light emitting material” refers exclusively to electroluminescent perovskite light emitting material that is emissive through electrical excitation. Wherever “perovskite light emitting material” is referred to in the text, it should be understood that reference is being made to electroluminescent perovskite light emitting material. This nomenclature may differ slightly from that used by other sources.

In general, PeLED devices may be photoluminescent or electroluminescent. As used herein, the term “PeLED” refers exclusively to electroluminescent devices that comprise electroluminescent perovskite light emitting material. When current is applied to such PeLED devices, the anode injects holes and the cathode injects electrons into the emissive layer(s). The injected holes and electrons each migrate towards the oppositely charged electrode. When an electron and a hole localize, an exciton, which is a localized electron-hole pair having an excited energy state, may be formed. Light is emitted if the exciton relaxes via a photo-emissive mechanism. The term “PeLED” may be used to describe single emissive unit electroluminescent devices that comprise electroluminescent perovskite light emitting material. The term “PeLED” may also be used to describe one or more emissive units of stacked electroluminescent devices that comprise electroluminescent perovskite light emitting material. This nomenclature may differ slightly from that used by other sources.

As used herein, the term “organic” includes polymeric materials as well as small molecule organic materials that may be used to fabricate optoelectronic devices, such as OLEDs. As used herein, the term small molecule refers to any organic material that is not a polymer, and small molecules may actually be quite large. Small molecules may include repeat units in some circumstances. For example, using a long chain alkyl group as a substituent does not remove a molecule from the small molecule class. Small molecules may also be incorporated into polymers, for example as a pendant group on a polymer backbone or as part of the backbone. Small molecules may also serve as the core moiety of a dendrimer, which consists of a series of chemical shells built on the core moiety. The core moiety of a dendrimer may be a small molecule. A dendrimer may be a small molecule and it is believed that all dendrimers currently used in the field of OLEDs are small molecules.

As used herein the term “organic light emitting material” includes fluorescent and phosphorescent organic light emitting materials, as well as organic materials that emit light through mechanisms such as triplet-triplet annihilation (TTA) or thermally activated delayed fluorescence (TADF). One example of organic light emitting material that emits red light is Bis(2-(3,5-dimethylphenyl)quinoline-C2,N′) (acetylacetonato) iridium(III) Ir(dmpq)₂(acac). One example of organic light emitting material that emits green light is tris(2-phenylpyridine)iridium (Ir(ppy)₃). One example of organic light emitting material that emits blue light is Bis[2-(4,6-difluorophenyl)pyridinato-C2,N](picolinato)iridium(III) (Flrpic).

In general, OLED devices may be photoluminescent or electroluminescent. As used herein, the term “OLED” refers exclusively to electroluminescent devices that comprise electroluminescent organic light emitting material. When current is applied to such OLED devices, the anode injects holes and the cathode injects electrons into the emissive layer(s). The injected holes and electrons each migrate towards the oppositely charged electrode. When an electron and a hole localize, an exciton, which is a localized electron-hole pair having an excited energy state, may be formed. Light is emitted if the exciton relaxes via a photo-emissive mechanism. The term “OLED” may be used to describe single emissive unit electroluminescent devices that comprise electroluminescent organic light emitting material. The term “OLED” may also be used to describe one or more emissive units of stacked electroluminescent devices that comprise electroluminescent organic light emitting material. This nomenclature may differ slightly from that used by other sources.

As used herein, the term “quantum dot” includes quantum dot material, quantum rod material and other luminescent nanocrystal material, with the exception of “perovskite” material, which is defined separately herein. Quantum dots may generally be considered as semiconductor nanoparticles that exhibit properties that are intermediate between bulk semiconductors and discrete molecules. Quantum dots may comprise III-V semiconductor material, such as gallium nitride (GaN), gallium phosphide (GaP), gallium arsenide (GaAs), indium phosphide (InP) and indium arsenide (InAs), or II-VI semiconductor material, such as zinc oxide (ZnO), zinc sulfide (ZnS), cadmium sulfide (CdS), cadmium selenide (CdSe) and cadmium telluride (CdTe), or combinations thereof. In general, as a result of quantum confinement effects, optoelectronic properties of quantum dots may change as a function of size or shape of the quantum dot.

Several types of quantum dot may be stimulated to emit light in response to optical or electrical excitation. That is to say that quantum dot light emitting material may be photoluminescent or electroluminescent. As used herein, the term “quantum dot light emitting material” refers exclusively to electroluminescent quantum dot light emitting material that is emissive through electrical excitation. Wherever “quantum dot light emitting material” is referred to in the text, it should be understood that reference is being made to electroluminescent quantum dot light emitting material. This nomenclature may differ slightly from that used by other sources.

As used herein, the term “quantum dot” does not include “perovskite” material. Several types of perovskite material, such as perovskite nanocrystals, 2D perovskite materials and Quasi-2D perovskite materials, are semiconducting materials that exhibit properties intermediate between bulk semiconductors and discrete molecules, where in a similar manner to quantum dots, quantum confinement may affect optoelectronic properties. However, as used herein, such materials are referred to as “perovskite” materials and not “quantum dot” materials. A first reason for this nomenclature is that perovskite materials and quantum dot materials, as defined herein, generally comprise different crystal structures. A second reason for this nomenclature is that perovskite materials and quantum dot materials, as defined herein, generally comprise different material types within their structures. A third reason for this nomenclature is that emission from perovskite material is generally independent of the structural size of the perovskite material, whereas emission from quantum dot material is generally dependent on the structural size (e.g. core and shell) of the quantum dot material. This nomenclature may differ slightly from that used by other sources.

In general, quantum dot light emitting materials comprise a core. Optionally, the core may be surrounded by one or more shells. Optionally, the core and one or more shells may be surrounded by a passivation structure. Optionally, the passivation structure may comprise ligands bonded to the one or more shells. The size of the of the core and shell(s) may influence the optoelectronic properties of quantum dot light emitting material. Generally, as the size of the core and shell(s) is reduced, quantum confinement effects become stronger, and electroluminescent emission may be stimulated at shorter wavelength. For display applications, the diameter of the core and shell(s) structure is typically in the range of 1-10 nm. Quantum dots that emit blue light are typically the smallest, with core-shell(s) diameter in the approximate range of 1-2.5 nm. Quantum dots that emit green light are typically slightly larger, with core-shell(s) diameter in the approximate range of 2.5-4 nm. Quantum dots that emit red light are typically larger, with core-shell(s) diameter in the approximate range of 5-7 nm. It should be understood that these ranges are provided by way of example and to aid understanding, and are not intended to be limiting.

Examples of quantum dot light emitting materials include materials comprising a core of CdSe. CdSe has a bulk bandgap of 1.73 eV, corresponding to emission at 716 nm. However, the emission spectrum of CdSe may be adjusted across the visible spectrum by tailoring the size of the CdSe quantum dot. Quantum dot light emitting materials comprising a CdSe core may further comprise one or more shells, comprising CdS, ZnS or combinations thereof. Quantum dot light emitting materials comprising CdSe may further comprise a passivation structure, which may include ligands bonded to the shell(s). Quantum dot light emitting materials comprising CdSe/CdS or CdSe/ZnS core-shell structures may be tuned to emit red, green or blue light for application in displays and/or light panels.

Examples of quantum dot light emitting materials further include materials comprising a core of InP. InP has a bulk bandgap of 1.35 eV, corresponding to emission at 918 nm. However, the emission spectrum of InP may be adjusted across the visible spectrum by tailoring the size of the InP quantum dot. Quantum dot light emitting materials comprising a InP core may further comprise one or more shells of CdS, ZnS or combinations thereof. Quantum dot light emitting materials comprising InP may further comprise a passivation structure, which may include ligands bonded to the shell(s). Quantum dot light emitting materials comprising InP/CdS or InP/ZnS core-shell structures may be tuned to emit red, green or blue light for application in displays and/or light panels.

In general, QLED devices may be photoluminescent or electroluminescent. As used herein, the term “QLED” refers exclusively to electroluminescent devices that comprise electroluminescent quantum dot light emitting material. When current is applied to such QLED devices, the anode injects holes and the cathode injects electrons into the emissive layer(s). The injected holes and electrons each migrate towards the oppositely charged electrode. When an electron and a hole localize, an exciton, which is a localized electron-hole pair having an excited energy state, may be formed. Light is emitted if the exciton relaxes via a photo-emissive mechanism. The term “QLED” may be used to describe single emissive unit electroluminescent devices that comprise electroluminescent quantum dot light emitting material. The term “QLED” may also be used to describe one or more emissive units of stacked electroluminescent devices that comprise electroluminescent quantum dot light emitting material. This nomenclature may differ slightly from that used by other sources.

As used herein, “top” means furthest away from the substrate, while “bottom” means closest to the substrate. Where a first layer is described as “disposed over” a second layer, the first layer is disposed further away from the substrate. There may be other layers between the first and second layer, unless it is specified that the first layer is “in contact with” the second layer. Where a first layer is described as “in contact with” a second layer, the first layer is adjacent to the second layer. That is to say the first layer is in direct physical contact with the second layer, with no additional layers, gaps or spaces disposed between the first layer and the second layer.

As used herein, “solution processible” means capable of being dissolved, dispersed or transported in and/or deposited from a liquid medium, either in solution or suspension form.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) and electron affinities (EA) are measured as negative energies relative to a vacuum level, a higher HOMO energy level corresponds to an IP that is less negative. Similarly, a higher LUMO energy level corresponds to an EA that is less negative. On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. The definitions of HOMO and LUMO energy levels therefore follow a different convention than work functions.

As used herein, the term “optically coupled” refers to one or more elements of a device or structure that are arranged such that light may impart between the one or more elements. The one or more elements may be in contact or may be separated by a gap or any connection, coupling, link or the like that allows for imparting of light between the one or more elements. For example, one or more light emitting devices may be optically coupled to one or more colour altering layers through a transparent or semi-transparent substrate.

As used herein, and as would be generally understood by one skilled in the art, a light emitting device, such as a PeLED, OLED or QLED may be referred to as a “stacked” light emitting device if two or more emissive units are separated by one or more charge generation layers within the layer structure of the light emitting device. In some sources, a stacked light emitting device may be referred to as a tandem light emitting device. It should be understood that the terms “stacked” and “tandem” may be used interchangeably, and as used herein, a tandem light emitting device is also considered to be a stacked light emitting device. This nomenclature may differ slightly from that used by other sources.

It should be understood that PeLEDs, OLEDs and QLEDs are light emitting diodes, and as used herein, a light emitting diode is considered to be a light emitting device that allows substantial current flow in only one direction. PeLEDs, OLEDs and QLEDs are therefore considered to be driven by direct current (DC) and not alternating current (AC). As used herein, the terms “PeLED”, “OLED” and “QLED” may be used to describe single emissive unit electroluminescent devices that respectively comprise electroluminescent perovskite, organic or quantum dot light emitting materials. The terms “PeLED”, “OLED” and “QLED” may also be used to describe one or more emissive units of stacked electroluminescent devices that respectively comprise electroluminescent perovskite, organic or quantum dot light emitting materials. It should therefore be understood that electroluminescent light emitting devices disclosed herein allow substantial current flow in only one direction through their respective PeLED, OLED and/or QLED emissive units. The electroluminescent light emitting devices disclosed herein are therefore considered to be driven by direct current (DC) and not alternating current (AC). This nomenclature may differ slightly from that used by other sources.

### SUMMARY

A light emitting device is provided. In one embodiment, the light emitting device comprises a first electrode, a second electrode and at least two emissive layers. The at least two emissive layers are disposed between the first electrode and the second electrode. A first emissive layer of the at least two emissive layers is disposed over the first electrode. A second emissive layer of the at least two emissive layers is disposed over the first emissive layer. The second electrode is disposed over the second emissive layer. The first emissive layer is in contact with the second emissive layer. At least one emissive layer of the at least two emissive layers comprises a perovskite light emitting material. The device comprises at least one further emissive layer of the at least two emissive layers, wherein the at least one further emissive layer of the at least two emissive layers comprises a perovskite light emitting material, an organic light emitting material or a quantum dot light emitting material.

In one embodiment, the first emissive layer comprises a perovskite light emitting material, and the second emissive layer comprises a perovskite light emitting material, an organic light emitting material or a quantum dot light emitting material. In one embodiment, the first emissive layer comprises a perovskite light emitting material, an organic light emitting material or a quantum dot light emitting material, and the second emissive layer comprises a perovskite light emitting material.

In one embodiment, the at least one further emissive layer of the at least two emissive layers comprises a perovskite light emitting material or an organic light emitting material. In one embodiment, the first emissive layer comprises a perovskite light emitting material, and the second emissive layer comprises a perovskite light emitting material. In one embodiment, the at least one further emissive layer of the at least two emissive layers comprises an organic light emitting material. In one embodiment, the first emissive layer comprises a perovskite light emitting material, and the second emissive layer comprises an organic light emitting material. In one embodiment, the first emissive layer comprises an organic light emitting material, and the second emissive layer comprises a perovskite light emitting material. In one embodiment, the at least one further emissive layer of the at least two emissive layers comprises a perovskite light emitting material or a quantum dot light emitting material. In one embodiment, the first emissive layer comprises a perovskite light emitting material, and the second emissive layer comprises a perovskite light emitting material. In one embodiment, the at least one further emissive layer of the at least two emissive layers comprises a quantum dot light emitting material. In one embodiment, the first emissive layer comprises a perovskite light emitting material, and the second emissive layer comprises a quantum dot light emitting material. In one embodiment, the first emissive layer comprises a quantum dot light emitting material, and the second emissive layer comprises a perovskite light emitting material.

In one embodiment, one or more of the emissive layers of the device may comprise organic metal halide light-emitting perovskite material. In one embodiment, one or more of the emissive layers of the device may comprise inorganic metal halide light-emitting perovskite material.

In one embodiment, at least one emissive layer of the at least two emissive layers emits yellow light, and at least one further emissive layer of the at least two emissive layers emits blue light. In one embodiment, the light emitting device emits white light. In one embodiment, the light emitting device emits white light with colour rendering index greater than or equal to 80. In one embodiment, the light emitting device emits white light with a correlated colour temperature of approximately 6504K.

In one embodiment, at least one emissive layer of the at least two emissive layers emits red light, and at least one further emissive layer of the at least two emissive layers emits green light. In one embodiment, the light emitting device emits yellow light.

In one embodiment, the light emitting device comprises a first electrode, a second electrode and at least three emissive layers. The at least three emissive layers are disposed between the first electrode and the second electrode. A first emissive layer of the at least three emissive layers is disposed over the first electrode. A second emissive layer of the at least three emissive layers is disposed over the first emissive layer. A third emissive layer of the at least three emissive layers is disposed over the second emissive layer. The second electrode is disposed over the third emissive layer. The first emissive layer is in contact with the second emissive layer. The second emissive layer is in contact with the third emissive layer. At least one emissive layer of the at least three emissive layers comprises a perovskite light emitting material. The device comprises at least two further emissive layers of the at least three emissive layers, wherein the at least two further emissive layers of the at least three emissive layers each comprise a perovskite light emitting material, an organic light emitting material or a quantum dot light emitting material.

In one embodiment, the at least two further emissive layers of the at least three emissive layers each comprise a perovskite light emitting material or an organic light emitting material. In one embodiment, the first emissive layer comprises a perovskite light emitting material, the second emissive layer comprises a perovskite light emitting material, and the third emissive layer comprises a perovskite light emitting material. In one embodiment, at least one emissive layer of the at least two further emissive layers comprises an organic light emitting material.

In one embodiment, the at least two further emissive layers of the at least three emissive layers each comprise a perovskite light emitting material or a quantum dot emitting material. In one embodiment, the first emissive layer comprises a perovskite light emitting material, the second emissive layer comprises a perovskite light emitting material, and the third emissive layer comprises a perovskite light emitting material. In one embodiment, at least one emissive layer of the at least two further emissive layers comprises a quantum dot light emitting material.

In one embodiment, at least one emissive layer of the at least two further emissive layers comprises an organic light emitting material, and at least one emissive layer of the at least two further emissive layers comprises a quantum dot light emitting material.

In one embodiment, at least one emissive layer of the at least three emissive layers emits red light, at least one further emissive layer of the at least three emissive layers emits green light, and at least one further emissive layer of the at least three emissive layers emits blue light. In one embodiment, the light emitting device emits white light. In one embodiment, the light emitting device emits white light with colour rendering index greater than or equal to 80. In one embodiment, the light emitting device emits white light with a correlated colour temperature of approximately 6504K.

In one embodiment, the light emitting device is a stacked light emitting device. In one embodiment, the light emitting device comprises a first electrode, a second electrode, a first emissive unit, a second emissive unit, a charge generation layer and at least three emissive layers. The at least three emissive layers are disposed between the first electrode and the second electrode. A first emissive layer of the at least three emissive layers is disposed over the first electrode. A second emissive layer of the at least three emissive layers is disposed over the first emissive layer. A third emissive layer of the at least three emissive layers is disposed over the second emissive layer. The second electrode is disposed over the third emissive layer. The first emissive unit comprises the first emissive layer and the second emissive layer. The second emissive unit comprises the third emissive layer. The charge generation layer is disposed between the second emissive layer and the third emissive layer. The first emissive layer is in contact with the second emissive layer. At least one emissive layer of the at least three emissive layers comprises a perovskite light emitting material. The device comprises at least two further emissive layers of the at least three emissive layers, wherein the at least two further emissive layers of the at least three emissive layers each comprise a perovskite light emitting material, an organic light emitting material or a quantum dot light emitting material.

In one embodiment, at least one of the first emissive layer and the second emissive layer emits red light, at least one of the first emissive layer and the second emissive layer emits green light, and the third emissive layer emits blue light.

In one embodiment, the light emitting device is a stacked light emitting device. In one embodiment, the light emitting device comprises a first electrode, a second electrode, a first emissive unit, a second emissive unit, a charge generation layer and at least three emissive layers. The at least three emissive layers are disposed between the first electrode and the second electrode. A first emissive layer of the at least three emissive layers is disposed over the first electrode. A second emissive layer of the at least three emissive layers is disposed over the first emissive layer. A third emissive layer of the at least three emissive layers is disposed over the second emissive layer. The second electrode is disposed over the third emissive layer. The first emissive unit comprises the first emissive layer. The second emissive unit comprises the second emissive layer and the third emissive layer. The charge generation layer is disposed between the first emissive layer and the second emissive layer. The second emissive layer is in contact with the third emissive layer. At least one emissive layer of the at least three emissive layers comprises a perovskite light emitting material. The device comprises at least two further emissive layers of the at least three emissive layers, wherein the at least two further emissive layers of the at least three emissive layers each comprise a perovskite light emitting material, an organic light emitting material or a quantum dot light emitting material.

In one embodiment, the first emissive layer emits blue light, at least one of the second emissive layer and the third emissive layer emits red light, and at least one of the second emissive layer and the third emissive layer emits green light.

In one embodiment, the light emitting device includes a microcavity structure. In one embodiment, the light emitting device includes a colour altering layer.

In one embodiment, the light emitting device may be included in a sub-pixel of a display. In one embodiment, the light emitting device may be included in a light panel.

### DESCRIPTION OF THE DRAWINGS

The summary above, as well as the following detailed description of illustrative embodiments, is better understood when read in conjunction with the appended drawings. For the purpose of illustrating the present disclosure, exemplary constructions of the disclosure are shown in the drawings. However, the present disclosure is not limited to specific methods and instrumentalities disclosed herein. Moreover, those in the art will understand that the drawings are not to scale.

In the accompanying drawings, an underlined number is employed to represent an item over which the underlined number is positioned or an item to which the underlined number is adjacent. A non-underlined number relates to an item identified by a line linking the non-underlined number to the item. When a number is non-underlined and accompanied by an associated arrow, the non-underlined number is used to identify a general item at which the arrow is pointing. Embodiments of the present disclosure will now be described, by way of example only, with reference to the following:

FIG. 1 depicts a light emitting device.

FIG. 2 depicts an inverted light emitting device.

FIG. 3 depicts 3D perovskite light emitting material with structure ABX₃.

FIG. 4 depicts layered perovskite light emitting material with structure L₂(ABX₃)ₙ₋₁BX₄, where n=1, 3, 5, 10 and ∞.

FIG. 5 depicts an example of a nanocrystal of perovskite materials with a layered structure that resembles L₂(ABX₃)ₙ₋₁BX₄, where n=5.

FIG. 6 depicts a light emitting device comprising two emissive layers.

FIG. 7 depicts a light emitting device comprising three emissive layers.

FIG. 8 depicts a rendition of the CIE 1931 (x, y) colour space chromaticity diagram.

FIG. 9 depicts a rendition of the CIE 1931(x, y) colour space chromaticity diagram that also shows colour gamut for (a) DCI-P3 and (b) Rec. 2020 colour spaces

FIG. 10 depicts a rendition of the CIE 1931 (x, y) colour space chromaticity diagram that also shows colour gamut for (a) DCI-P3 and (b) Rec. 2020 colour spaces with colour coordinates for exemplary red, green and blue PeLED, OLED and QLED devices.

FIG. 11 depicts a rendition of the CIE 1931 (x, y) color space chromaticity diagram that also shows the Planckian Locus.

FIG. 12 depicts exemplary electroluminescence emission spectra for red, green and blue PeLEDs, OLEDs and QLEDs.

FIG. 13 depicts various configurations of emissive layers for a light emitting device comprising two emissive layers.

FIG. 14 depicts further various configurations of emissive layers for a light emitting device comprising two emissive layers.

FIG. 15 depicts various configurations of emissive layers for a light emitting device comprising three emissive layers.

FIG. 16 depicts further various configurations of emissive layers for a light emitting device comprising three emissive layers.

FIG. 17 depicts a stacked light emitting device comprising two emissive units.

FIG. 18 depicts a stacked light emitting device comprising two emissive units, wherein the first emissive unit comprises two emissive layers.

FIG. 19 depicts various configurations of emissive layers for a stacked light emitting device comprising three emissive layers.

FIG. 20 depicts further various configurations of emissive layers for a stacked light emitting device comprising three emissive layers.

FIG. 21 depicts an example of a stacked light emitting device comprising colour altering layers.

### DESCRIPTION OF EMBODIMENTS

General device architectures and operating principles for PeLEDs are substantially similar to those for OLEDs and QLEDs. Each of these light emitting devices comprises at least one emissive layer disposed between and electrically connected to an anode and a cathode. For a PeLED, the emissive layer comprises perovskite light emitting material. For an OLED, the emissive layer comprises organic light emitting material. For a QLED, the emissive layer comprises quantum dot light emitting material. For each of these light emitting devices, when a current is applied, the anode injects holes and the cathode injects electrons into the emissive layer(s). The injected holes and electrons each migrate towards the oppositely charged electrode. When an electron and a hole localize, an exciton, which is a localized electron-hole pair having an excited energy state, may be formed. Light is emitted if the exciton relaxes via a photo-emissive mechanism. Non-radiative mechanisms, such as thermal radiation and/or Auger recombination may also occur, but are generally considered undesirable. Substantial similarity between device architectures and working principles required for PeLEDs, OLEDs and QLEDs, facilitates the combination of perovskite light emitting material, organic light emitting material and quantum dot light emitting material in a single device, such as a light emitting device with multiple emissive layers.

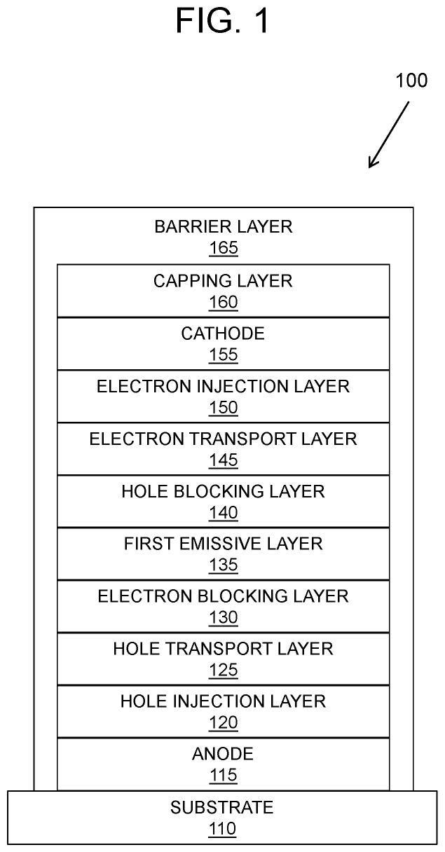

FIG. 1 shows a light emitting device 100 comprising a single emissive layer. Device 100 may include a substrate 110, an anode 115, a hole injection layer 120, a hole transport layer 125, an electron blocking layer 130, a first emissive layer 135, a hole blocking layer 140, an electron transport layer 145, an electron injection layer 150, a cathode 155, a capping layer 160, and a barrier layer 165. The first emissive layer 135 may comprise perovskite light emitting material, organic light emitting material or quantum dot light emitting material. Device 100 may be fabricated by depositing the layers described in order. As the device 100 has anode 115 disposed under cathode 155, device 100 may be referred to as a “standard” device architecture. For a PeLED, the emissive layer comprises perovskite light emitting material. For an OLED, the emissive layer comprises organic light emitting material. For a QLED, the emissive layer comprises quantum dot light emitting material.

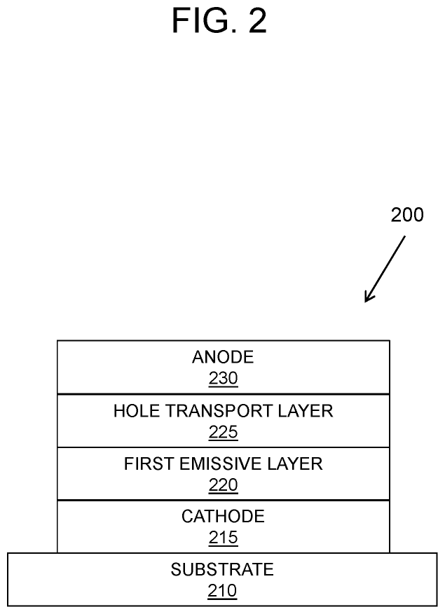

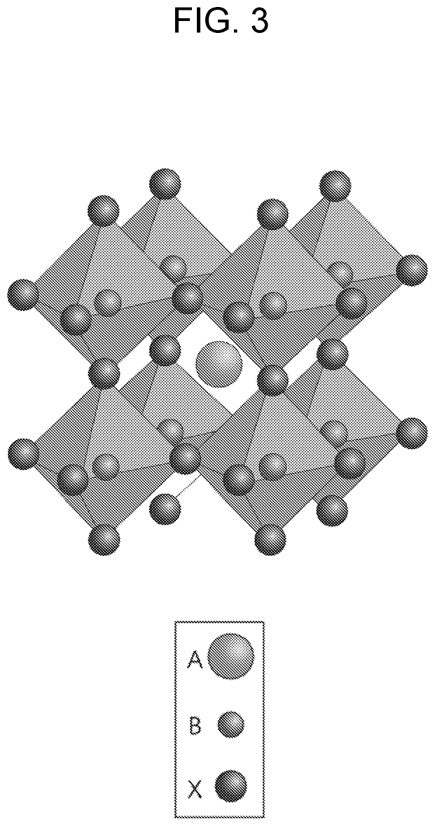

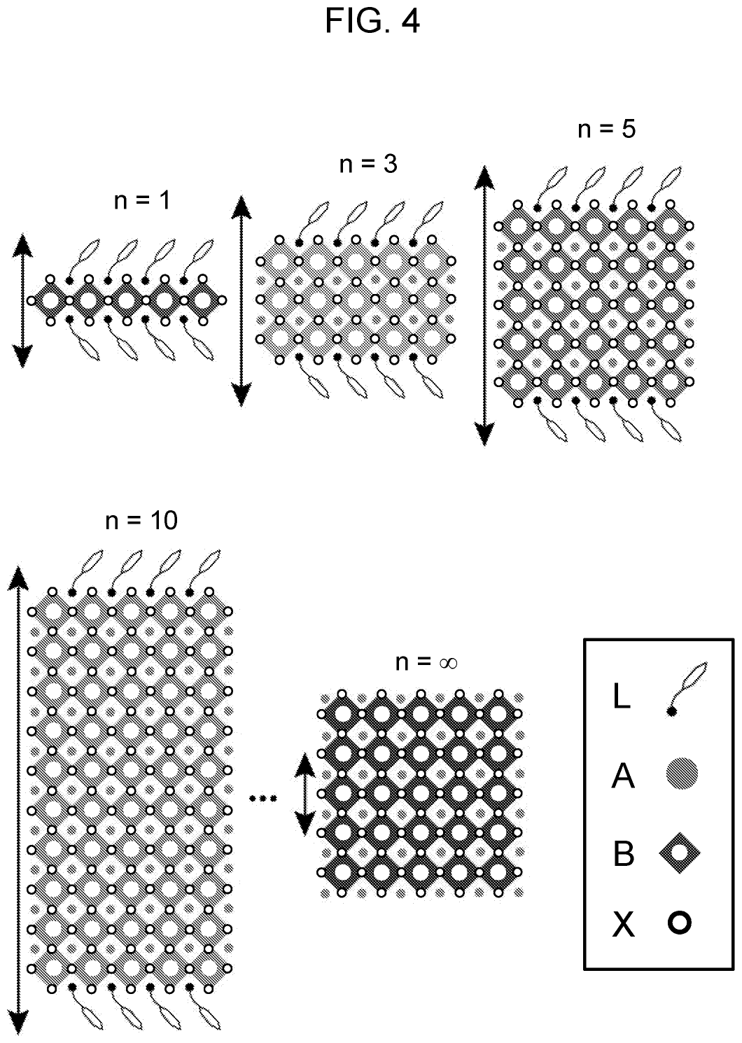

FIG. 2 shows an inverted light emitting device 200 comprising a single emissive layer. The light emitting device 200 may be a PeLED, OLED or QLED. The device includes a substrate 210, a cathode 215, a first emissive layer 220, a hole transport layer 225, and an anode 230. The first emissive layer 220 may comprise perovskite light emitting material, organic light emitting material or quantum dot light emitting material. Device 200 may be fabricated by depositing the layers described in order. As the device 200 has cathode 215 disposed under anode 230, device 200 may be referred to as an “inverted” device architecture. For a PeLED, the emissive layer comprises perovskite light emitting material. For an OLED, the emissive layer comprises organic light emitting material. For a QLED, the emissive layer comprises quantum dot light emitting material. Materials similar to those described with respect to device 100 may be used in the corresponding layers of device 200. FIG. 2 provides one example of how some layers may be omitted from the structure of a PeLED, OLED or QLED.

The simple layered structures illustrated in FIGS. 1 and 2 are provided by way of non-limiting examples, and it is understood that embodiments of the invention may be used in connection with a wide variety of other structures. The specific materials and structures described are exemplary in nature, and other materials and structures may be used. Functional PeLEDs, OLEDs and QLEDs may be achieved by combining the various layers described in different ways, or layers may be omitted entirely, based on factors such as performance, design and cost. Other layers, not specifically described, may also be included. Materials other than those specifically described may be used. Although many of the examples provided herein describe various layers as comprising a single material, it is understood that combinations of materials may be used. Also, the layers may have various sublayers. For example, the emissive layer of a PeLED may comprise one or more sub-layers of perovskite light emitting material disposed in contact with one or more sub-layers of organic or inorganic material. The organic or inorganic material in the one or more sub-layers may serve a charge injection, charge transport, charge blocking or charge confinement function within the emissive layer of the PeLED device. However, where such sub-layers of organic or inorganic material do not emit light through a process of electroluminescence as described in the foregoing, they are considered herein as sub-layers of the PeLED emissive layer and not as separate organic or inorganic emissive layers.

The names given to the various layers herein are not intended to be strictly limiting. For example, in a device, the hole transport layer may transport and inject holes into the emissive layer and may be described as a hole transport layer or a hole injection layer.

PeLEDs, OLEDs and QLEDs are generally intended to emit light through at least one of the electrodes, and one or more transparent electrodes may be useful in such optoelectronic devices. For example, a transparent electrode material, such as indium tin oxide (ITO), may be used for the bottom electrode, while a transparent electrode material, such as a thin metallic layer of a blend of magnesium and silver (Mg:Ag), may be used for the top electrode. For a device intended to emit light only through the bottom electrode, the top electrode does not need to be transparent, and may be comprised of an opaque and/or reflective layer, such as a metal layer having a high reflectivity. Similarly, for a device intended only to emit light through the top electrode, the bottom electrode may be opaque and/or reflective, such as a metal layer having a high reflectivity. Where an electrode does not need to be transparent, using a thicker layer may provide better conductivity and may reduce voltage drop and/or Joule heating in the device, and using a reflective electrode may increase the amount of light emitted through the other electrode by reflecting light back towards the transparent electrode. A fully transparent device may also be fabricated, where both electrodes are transparent.

Devices fabricated in accordance with embodiments of the present invention may optionally comprise a substrate 110. The substrate 110 may comprise any suitable material that provides the desired structural and optical properties. The substrate 110 may be rigid or flexible. The substrate 110 may be flat or curved. The substrate 110 may be transparent, translucent or opaque. Preferred substrate materials are glass, plastic and metal foil. Other substrates, such as fabric and paper may be used. The material and thickness of the substrate 110 may be chosen to obtain desired structural and optical properties. Substantial similarity between substrate properties required for PeLEDs, OLEDs and QLEDs facilitates the combination of perovskite light emitting material, organic light emitting material and quantum dot light emitting material in a single device, such as a light emitting device with multiple emissive layers.

Devices fabricated in accordance with embodiments of the present invention may optionally comprise an anode 115. The anode 115 may comprise any suitable material or combination of materials known to the art, such that the anode 115 is capable of conducting holes and injecting them into the layers of the device. Preferred anode 115 materials include conductive metal oxides, such as indium tin oxide (ITO), indium zinc oxide (IZO) and aluminum zinc oxide (AlZnO), metals such as silver (Ag), aluminum (Al), aluminum-neodymium (Al:Nd), gold (Au) and alloys thereof, or a combination thereof. Other preferred anode 115 materials include graphene, carbon nanotubes, nanowires or nanoparticles, silver nanowires or nanoparticles, organic materials, such as poly(3,4-ethylenedioxythiophene):polystyrene sulfonate (PEDOT:PSS) and derivatives thereof, or a combination thereof. Compound anodes comprising one or more anode materials in a single layer may be preferred for some devices. Multilayer anodes comprising one or more anode materials in one or more layers may be preferred for some devices. One example of a multilayer anode is ITO/Ag/ITO. In a standard device architecture for PeLEDs, OLEDs and QLEDs, the anode 115 may be sufficiently transparent to create a bottom-emitting device, where light is emitted through the substrate. One example of a transparent anode commonly used in a standard device architecture is a layer of ITO. Another example of a transparent anode commonly used in a standard device architecture is ITO/Ag/ITO, where the Ag thickness is less than approximately 25 nm. By including a layer of silver of thickness less than approximately 25 nm, the anode may be transparent as well as partially reflective. When such a transparent and partially reflective anode is used in combination with a reflective cathode, such as LiF/AI, this may have the advantage of creating a microcavity within the device. A microcavity may provide one or more of the following advantages: an increased total amount of light emitted from device, and therefore higher efficiency and brightness; an increased proportion of light emitted in the forward direction, and therefore increased apparent brightness at normal incidence; and spectral narrowing of the emission spectrum, resulting in light emission with increased colour saturation. The anode 115 may be opaque and/or reflective. In a standard device architecture for PeLEDs, OLEDs and QLEDs, a reflective anode 115 may be preferred for some top-emitting devices to increase the amount of light emitted from the top of the device. One example of a reflective anode commonly used in a standard device architecture is a multilayer anode of ITO/Ag/ITO, where the Ag thickness is greater than approximately 80 nm. When such a reflective anode is used in combination with a transparent and partially reflective cathode, such as Mg:Ag, this may have the advantage of creating a microcavity within the device. The material and thickness of the anode 115 may be chosen to obtain desired conductive and optical properties. Where the anode 115 is transparent, there may be a range of thicknesses for a particular material that is thick enough to provide the desired conductivity, yet thin enough to provide the desired degree of transparency. Other materials and structures may be used. Substantial similarity between anode properties required for PeLEDs, OLEDs and QLEDs facilitates the combination of perovskite light emitting material, organic light emitting material and quantum dot light emitting material in a single device, such as a light emitting device with multiple emissive layers.

Devices fabricated in accordance with embodiments of the present invention may optionally comprise a hole transport layer 125. The hole transport layer 125 may include any material capable of transporting holes. The hole transport layer 125 may be deposited by a solution process or by a vacuum deposition process. The hole transport layer 125 may be doped or undoped. Doping may be used to enhance conductivity.

Examples of undoped hole transport layers are N,N′-Di(1-naphthyl)-N,N′-diphenyl-(1,1′-biphenyl)-4,4′-diamine (NPD), poly[(9,9-dioctylfluorenyl-2,7-diyl)-co-(4,4′-(N-(4-sec-butylphenyl) diphenylamine (TFB), poly[N,N′-bis(4-butylphenyl)-N,N′-bis(phenyl)-benzidine] (poly-TPD), poly(9-vinylcarbazole) (PVK), 4,4′-Bis(N-carbazolyl)-1,1′-biphenyl (CBP), Spiro-OMeTAD and molybdenum oxide (MoO₃). One example of a doped hole transport layer is 4,4′,4″-Tris[phenyl(m-tolyl)amino]triphenylamine (m-MTDATA) doped with F₄-TCNQ at a molar ratio of 50:1. One example of a solution-processed hole transport layer is PEDOT:PSS. Other hole transport layers and structures may be used. The preceding examples of hole transport materials are especially well-suited to application in PeLEDs. However, these materials may also be implemented effectively in OLEDs and QLEDs. Substantial similarity between hole transport layer properties required for perovskite light emitting material, organic light emitting material and quantum dot light emitting material facilitates the combination of these light emitting materials in a single device, such as a light emitting device with multiple emissive layers.

Devices fabricated in accordance with embodiments of the present invention may optionally comprise one or more emissive layers 135. The emissive layer 135 may include any material capable of emitting light when a current is passed between anode 115 and cathode 155. Device architectures and operating principles are substantially similar for PeLEDs, OLEDs and QLEDs. However, these light emitting devices may be distinguished by differences in their respective emissive layers. The emissive layer of a PeLED may comprise perovskite light emitting material. The emissive layer of an OLED may comprise organic light emitting material. The emissive layer of a QLED may comprise quantum dot light emitting material.

Examples of perovskite light-emitting materials include 3D perovskite materials, such as methylammonium lead iodide (CH₃NH₃PbI₃), methylammonium lead bromide (CH₃NH₃PbBr₃), methylammonium lead chloride (CH₃NH₃PbCl₃), formamidinium lead iodide (CH(NH₂)₂PbI₃), formamidinium lead bromide (CH(NH₂)₂PbBr₃), formamidinium lead chloride (CH(NH₂)₂PbCl₃), caesium lead iodide (CsPbI₃), caesium lead bromide (CsPbBr₃) and caesium lead chloride (CsPbCl₃). Examples of perovskite light-emitting materials further include 3D perovskite materials with mixed halides, such as CH₃NH₃PbI₃₋ₓClₓ, CH₃NH₃PbI₃₋ₓBrₓ, CH₃NH₃PbCl₃₋ₓBrₓ, CH(NH₂)₂PbI₃₋ₓBrₓ, CH(NH₂)₂PbI₃₋ₓClₓ, CH(NH₂)₂PbCl₃₋ₓBrₓ, CsPbI₃₋ₓClₓ, CsPbI₃₋ₓBrₓ and CsPbCl₃₋ₓBrₓ, where x is in the range of 0-3. Examples of perovskite light-emitting materials further include 2D perovskite materials such as (C₁₀H₇CH₂NH₃)₂PbI₄, (C₁₀H₇CH₂NH₃)₂PbBr₄, (C₁₀H₇CH₂NH₃)₂PbCl₄, (C₆H₅C₂H₄NH₃)₂PbI₄, (C₆H₅C₂H₄NH₃)₂PbBr₄ and (C₆H₅C₂H₄NH₃)₂PbCl₄, 2D perovskite materials with mixed halides, such as (C₁₀H₇CH₂NH₃)₂PbI₃₋ₓClₓ, (C₁₀H₇CH₂NH₃)₂PbI₃₋ₓBrₓ, (C₁₀H₇CH₂NH₃)₂PbCl₃₋ₓBrₓ, (C₆H₅C₂H₄NH₃)₂PbI₃₋ₓClₓ, (C₆H₅C₂H₄NH₃)₂PbI₃₋ₓBrₓ and (C₆H₅C₂H₄NH₃)₂PbCl₃₋ₓBrₓ, where x is in the range of 0-3. Examples of perovskite light-emitting materials further include Quasi-2D perovskite materials, such as (C₆H₅C₂H₄NH₃)₂(CH(NH₂)₂PbBr₃)ₙ₋₁PbI₄, (C₆H₅C₂H₄NH₃)₂(CH(NH₂)₂PbBr₃)ₙ₋₁PbBr₄, (C₆H₅C₂H₄NH₃)₂(CH(NH₂)₂PbBr₃)ₙ₋₁PbCl₄, (C₁₀H₇CH₂NH₃)₂(CH₃NH₃PbI₂Br)ₙ₋₁PbI₄, (C₁₀H₇CH₂NH₃)₂(CH₃NH₃PbI₂Br)ₙ₋₁PbBr₄ and (C₁₀H₇CH₂NH₃)₂(CH₃NH₃PbI₂Br)ₙ₋₁PbCl₄, where n is the number of layers, and, optionally, n may be in the range of about 2-10. Examples of perovskite light-emitting materials further include Quasi-2D perovskite materials with mixed halides, such as (C₆H₅C₂H₄NH₃)₂(CH(NH₂)₂PbBr₃)ₙ₋₁PbI₃₋ₓClₓ, (C₆H₅C₂H₄NH₃)₂(CH(NH₂)₂PbBr₃)ₙ₋₁PbI₃₋ₓBrₓ, (C₆H₅C₂H₄NH₃)₂(CH(NH₂)₂PbBr₃)ₙ₋₁PbCl₃₋ₓBrₓ, (C₁₀H₇CH₂NH₃)₂(CH₃NH₃PbI₂Br)ₙ₋₁PbI₃₋ₓClₓ, (C₁₀H₇CH₂NH₃)₂(CH₃NH₃PbI₂Br)ₙ₋₁PbI₃₋ₓBrₓ and (C₁₀H₇CH₂NH₃)₂(CH₃NH₃PbI₂Br)ₙ₋₁PbCl₃₋ₓBrₓ, where n is the number of layers, and, optionally, n may be in the range of about 2-10, and x is in the range of 0-3. Examples of perovskite light-emitting materials further include any of the aforementioned examples, where the divalent metal cation lead (Pb⁺) may be replaced with tin (Sn⁺), copper (Cu⁺) or europium (Eu⁺). Examples of perovskite light-emitting materials further include perovskite light-emitting nanocrystals with structures that closely resemble Quasi-2D perovskite materials.

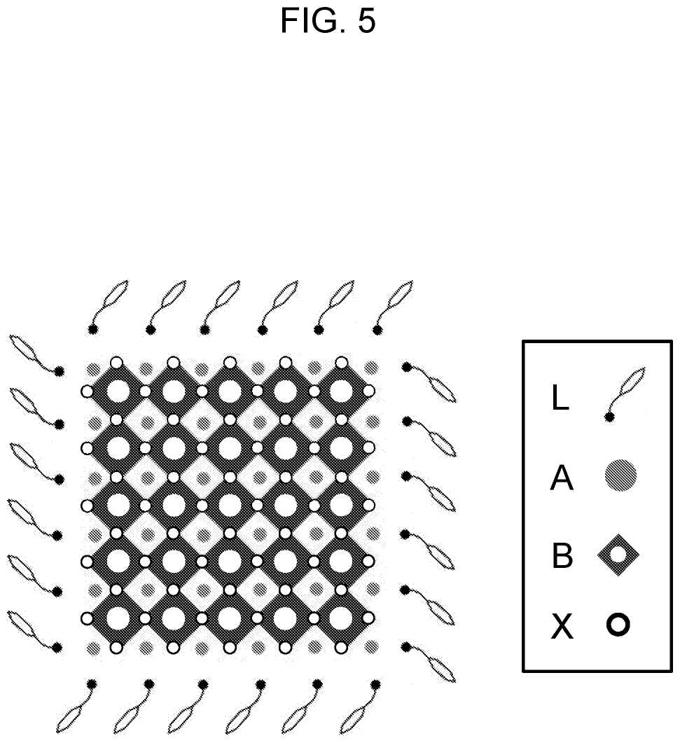

Perovskite light emitting material may comprise organic metal halide perovskite material, such as methylammonium lead iodide (CH₃NH₃PbI₃), methylammonium lead bromide (CH₃NH₃PbBr₃), methylammonium lead chloride (CH₃NH₃PbCl₃), where the materials comprises an organic cation. Perovskite light emitting material may comprise inorganic metal halide perovskite material, such as caesium lead iodide (CsPbI₃), caesium lead bromide (CsPbBr₃) and caesium lead chloride (CsPbCl₃), where the material comprises an inorganic cation. Furthermore, perovskite light emitting material may comprise perovskite light emitting material where there is a combination of organic and inorganic cations. The choice of an organic or inorganic cation may be determined by several factors, including desired emission colour, efficiency of electroluminescence, stability of electroluminescence and ease of processing. Inorganic metal halide perovskite material may be particularly well-suited to perovskite light-emitting materials with a nanocrystal structure, such as those depicted in FIG. 5, wherein an inorganic cation may enable a compact and stable perovskite light-emitting nanocrystal structure.

Perovskite light emitting material may be included in the emissive layer 135 in a number of ways. For example, the emissive layer may comprise 2D perovskite light-emitting material, Quasi-2D perovskite light-emitting material or 3D perovskite light-emitting material, or a combination thereof. Optionally, the emissive layer may comprise perovskite light emitting nanocrystals. Optionally, the emissive layer 135 may comprise an ensemble of Quasi-2D perovskite light emitting materials, where the Quasi-2D perovskite light emitting materials in the ensemble may comprise a different number of layers. An ensemble of Quasi-2D perovskite light emitting materials may be preferred because there may be energy transfer from Quasi-2D perovskite light emitting materials with a smaller number of layers and a larger energy band gap to Quasi-2D perovskite light emitting materials with a larger number of layers and a lower energy band gap. This energy funnel may efficiently confine excitons in a PeLED device, and may improve device performance. Optionally, the emissive layer 135 may comprise perovskite light emitting nanocrystal materials. Perovskite light emitting nanocrystal materials may be preferred because nanocrystal boundaries may be used to confine excitons in a PeLED device, and surface cations may be used to passivate the nanocrystal boundaries. This exciton confinement and surface passivation may improve device performance. Other emissive layer materials and structures may be used.

Optionally, the light emitting device may comprise a single emissive layer comprising perovskite light emitting material. Optionally, the light emitting device may further comprise one or more additional emissive layers comprising perovskite light emitting material, organic light emitting material and/or quantum dot light emitting material. Optionally, the light emitting device may comprise at least one emissive layer comprising perovskite light emitting material and at least one further emissive layer comprising perovskite light emitting material, organic light emitting material or quantum dot light emitting material. Optionally, the light emitting device may comprise at least one emissive layer comprising perovskite light emitting material and at least two further emissive layers, each comprising perovskite light emitting material, organic light emitting material or quantum dot light emitting material.

A multiple emissive layer device may be preferred, for example, to enable light from multiple emissive layers to be combined to enhance efficiency, lifetime and/or tune emission colour of the device. For example, multiple emission colours from multiple emissive layers may be combined within a device. For example, red light from a first emissive layer may be combined with green light from a second emissive layer and blue light from a third emissive layer to generate white light emission from the device. A multiple emissive layer device may further enable light emission from one or more perovskite light emitting materials to be combined with light emission from one or more perovskite light emitting materials, organic light emitting materials and/or quantum dot light emitting materials, wherein the optimum type of light emitting material may be selected for each respective colour.

Several examples of fluorescent organic light emitting materials are described in European patent EP 0423283 B1. Several examples of phosphorescent organic light emitting materials are described in United States patents U.S. Pat. No. 6,303,238 B1 and U.S. Pat. No. 7,279,704 B2. Several examples of organic light emitting materials that emit through a TADF mechanism are described in Uoyama et al. Several examples of quantum dot light emitting materials are described in Kathirgamanathan et al. (1). All of these citations are included herein by reference in their entirety.

Devices fabricated in accordance with embodiments of the present invention may optionally comprise an electron transport layer 145. The electron transport layer 145 may include any material capable of transporting electrons. The electron transport layer 145 may be deposited by a solution process or by a vacuum deposition process. The electron transport layer 145 may be doped or undoped. Doping may be used to enhance conductivity.

Examples of undoped electron transport layers are tris(8-hydroxyquinolinato)aluminum (Alq₃), 2,2′,2″-(1,3,5-Benzinetriyl)-tris(1-phenyl-1-H-benzimidazole) (TPBi), 2,9-Dimethyl-4,7-diphenyl-1,10-phenanthroline (BCP), zinc oxide (ZnO) and titanium dioxide (TiO₃). One example of a doped electron transport layer is 4,7-diphenyl-1,10-phenanthroline (BPhen) doped with lithium (Li) at a molar ratio of 1:1. One example of a solution-processed electron transport layer is [6,6]-Phenyl C61 butyric acid methyl ester (PCBM). Other electron transport layers and structures may be used. The preceding examples of electron transport materials are especially well-suited to application in PeLEDs. However, these materials may also be implemented effectively in OLEDs and QLEDs. Substantial similarity between electron transport layer properties required for perovskite light emitting material, organic light emitting material and quantum dot light emitting material facilitates the combination of these light emitting materials in a single device, such as a light emitting device with multiple emissive layers.

Devices fabricated in accordance with embodiments of the present invention may optionally comprise a cathode 155. The cathode 155 may comprise any suitable material or combination of materials known to the art, such that the cathode 155 is capable of conducting electronics and injecting them into the layers of the device. Preferred cathode 155 materials include metal oxides, such as indium tin oxide (ITO), indium zinc oxide (IZO) and fluorine tin oxide (FTO), metals, such as calcium (Ca), barium (Ba), magnesium (Mg) and ytterbium (Yb) or a combination thereof. Other preferred cathode 155 materials include metals such as silver (Ag), aluminum (Al), aluminum-neodymium (Al:Nd), gold (Au) and alloys thereof, or a combination thereof. Compound cathodes comprising one or more cathode materials in a single layer may be preferred from some devices. One example of a compound cathode is Mg:Ag. Multilayer cathodes comprising one or more cathode materials in one or more layers may be preferred for some devices. One example of a multilayer cathode is Ba/Al. In a standard device architecture for PeLEDs, OLEDs and QLEDs, the cathode 155 may be sufficiently transparent to create a top-emitting device, where light is emitted from the top of the device. One example of a transparent cathode commonly used in a standard device architecture is a compound layer of Mg:Ag. By using a compound of Mg:Ag, the cathode may be transparent as well as partially reflective. When such a transparent and partially reflective cathode is used in combination with a reflective anode, such as ITO/Ag/ITO, where the Ag thickness is greater than approximately 80 nm, this may have the advantage of creating a microcavity within the device. The cathode 155 may be opaque and/or reflective. In a standard device architecture for PeLEDs, OLEDs and QLEDs, a reflective cathode 155 may be preferred for some bottom-emitting devices to increase the amount of light emitted through the substrate from the bottom of the device. One example of a reflective cathode commonly used in a standard device architecture is a multilayer cathode of LiF/Al. When such a reflective cathode is used in combination with a transparent and partially reflective anode, such as ITO/Ag/ITO, where the Ag thickness is less than approximately 25 nm, this may have the advantage of creating a microcavity within the device.

The material and thickness of the cathode 155 may be chosen to obtain desired conductive and optical properties. Where the cathode 155 is transparent, there may be a range of thicknesses for a particular material that is thick enough to provide the desired conductivity, yet thin enough to provide the desired degree of transparency. Other materials and structures may be used. Substantial similarity between cathode properties required for PeLEDs, OLEDs and QLEDs facilitates the combination of perovskite light emitting material, organic light emitting material and quantum dot light emitting material in a single device, such as a light emitting device with multiple emissive layers.

Devices fabricated in accordance with embodiments of the present invention may optionally comprise one or more blocking layers. Blocking layers may be used to reduce the number of charge carriers (electrons or holes) and/or excitons exiting the emissive layer. An electron blocking layer 130 may be disposed between the emissive layer 135 and the hole transport layer 125 to block electrons from leaving the emissive layer 135 in the direction of the hole transport layer 125. Similarly, a hole blocking layer 140 may be disposed between the emissive layer 135 and the electron transport layer 145 to block holes from leaving the emissive layer 135 in the direction of the electron transport layer 145. Blocking layers may also be used to block excitons from diffusing from the emissive layer. As used herein, and as would be understood by one skilled in the art, the term “blocking layer” means that the layer provides a barrier that significantly inhibits transport of charge carriers and/or excitons, without suggesting that the layer completely blocks the charge carriers and/or excitons. The presence of such a blocking layer in a device may result in substantially higher efficiencies as compared to a similar device lacking a blocking layer. A blocking layer may also be used to confine emission to a desired region of a device. Substantial similarity between blocking layer properties required for perovskite light emitting material, organic light emitting material and quantum dot light emitting material facilitates the combination of these light emitting materials in a single device, such as a light emitting device with multiple emissive layers.

Devices fabricated in accordance with embodiments of the present invention may optionally comprise one or more injection layers. Generally, injection layers are comprised of one or more materials that may improve the injection of charge carriers from one layer, such as an electrode, into an adjacent layer. Injection layers may also perform a charge transport function.

In device 100, the hole injection layer 120 may be any layer that improves the injection of holes from the anode 115 into the hole transport layer 125. Examples of materials that may be used as a hole injection layer are Copper(II)phthalocyanine (CuPc) and 1,4,5,8,9,11-Hexaazatriphenylenehexacarbonitrile (HATCN), which may be vapor deposited, and polymers, such as PEDOT:PSS, which may be deposited from solution. Another example of a material that may be used as a hole injection layer is molybdenum oxide (MoO₃). The preceding examples of hole injection materials are especially well-suited to application in PeLEDs. However, these materials may also be implemented effectively in OLEDs and QLEDs. Substantial similarity between hole injection layer properties required for perovskite light emitting material, organic light emitting material and quantum dot light emitting material facilitates the combination of these light emitting materials in a single device, such as a light emitting device with multiple emissive layers.

A hole injection layer (HIL) 120 may comprise a charge carrying component having HOMO energy level that favourably matches, as defined by their herein-described relative IP energies, with the adjacent anode layer on one side of the HIL, and the hole transporting layer on the opposite side of the HIL. The “charge carrying component” is the material responsible for the HOMO energy level that actually transports the holes. This material may be the base material of the HIL, or it may be a dopant. Using a doped HIL allows the dopant to be selected for its electrical properties, and the host to be selected for morphological properties, such as ease of deposition, wetting, flexibility, toughness, and others. Preferred properties of the HIL material are such that holes can be efficiently injected from the anode into the HIL material. The charge carrying component of the HIL 120 preferably has an IP not more than about 0.5 eV greater than the IP of the anode material. Similar conditions apply to any layer into which holes are being injected. HIL materials are further distinguished from conventional hole transporting materials that are typically used in the hole transporting layer of a PeLED, OLED or QLED in that such HIL materials may have a hole conductivity that is substantially less than the hole conductivity of conventional hole transporting materials. The thickness of the HIL 120 of the present invention may be thick enough to planarize the anode and enable efficient hole injection, but thin enough not to hinder transportation of holes. For example, an HIL thickness of as little as 10 nm may be acceptable. However, for some devices, an HIL thickness of up to 50 nm may be preferred.

In device 100, the electron injection layer 150 may be any layer that improves the injection of electrons from the cathode 155 into the electron transport layer 145. Examples of materials that may be used as an electron injection layer are inorganic salts, such as lithium fluoride (LiF), sodium fluoride (NaF), barium fluoride (BaF), caesium fluoride (CsF), and caesium carbonate (CsCO₃). Other examples of materials that may be used as an electron injection layer are metal oxides, such as zinc oxide (ZnO) and titanium oxide (TiO₂), and metals, such as calcium (Ca), barium (Ba), magnesium (Mg) and ytterbium (Yb). Other materials or combinations of materials may be used for injection layers. Depending on the configuration of a particular device, injection layers may be disposed at locations different than those shown in device 100. The preceding examples of electron injection materials are all especially well-suited to application in PeLEDs. However, these materials may also be implemented effectively in OLEDs and QLEDs. Substantial similarity between electron injection layer properties required for perovskite light emitting material, organic light emitting material and quantum dot light emitting material facilitates the combination of these light emitting materials in a single device, such as a light emitting device with multiple emissive layers.

Devices fabricated in accordance with embodiments of the present invention may optionally comprise a capping layer 160. The capping layer 160 may include any material capable of enhancing light extraction from the device. Preferably, the capping layer 160 is disposed over the top electrode in a top-emitting device architecture. Preferably, the capping layer 160 has a refractive index of at least 1.7, and is configured to enhance passage of light from the emissive layer 135 through the top electrode and out of the device, thereby enhancing device efficiency. Examples of materials that may be used for the capping layer 160 are 4,4′-Bis(N-carbazolyl)-1,1′-biphenyl (CBP), Alq₃, and more generally, triamines and arylenediamines. The capping layer 160 may comprise a single layer or multiple layers. Other capping layer materials and structures may be used. Substantial similarity between capping layer properties required for perovskite light emitting materials, organic light emitting materials and quantum dot light emitting materials facilitates the combination of these light emitting devices in a single device, such as a light emitting device with multiple emissive layers.

Devices fabricated in accordance with embodiments of the present invention may optionally comprise a barrier layer 165. One purpose of the barrier layer 165 is to protect device layers from damaging species in the environment, including moisture, vapour and/or gasses. Optionally, the barrier layer 165 may be deposited over, under or next to the substrate, electrode, or any other parts of the device, including an edge. Optionally, the barrier layer 165 may be a bulk material such as glass or metal, and the bulk material may be affixed over, under of next to the substrate, electrode, or any other parts of the device. Optionally, the barrier layer 165 may be deposited onto a film, and the film may be affixed over, under of next to the substrate, electrode, or any other parts of the device. Where the barrier layer 165 is deposited onto a film, preferred film materials comprise glass, plastics, such as polyethylene terephthalate (PET) and polyethylene naphthalate (PEN) and metal foils. Where the barrier layer 165 is a bulk material or deposited onto a film, preferred materials used to affix the film or bulk material to the device include thermal or UV-curable adhesives, hot-melt adhesives and pressure sensitive adhesives.

The barrier layer 165 may be a bulk material or formed by various known deposition techniques, including sputtering, vacuum thermal evaporation, electron-beam deposition and chemical vapour deposition (CVD) techniques, such as plasma-enhanced chemical vapour deposition (PECVD) and atomic layer deposition (ALD). The barrier layer 165 may include compositions having a single phase as well as compositions having multiple phases. Any suitable material or combination of materials may be used for the barrier layer 165. The barrier layer 165 may incorporate organic or inorganic compounds or both. Preferred inorganic barrier layer materials include aluminum oxides such as Al₂O₃, silicon oxides such as SiO₂, silicon nitrides such as SiNₓ and bulk materials such as glasses and metals. Preferred organic barrier layer materials include polymers. The barrier layer 165 may comprise a single layer or multiple layers. Multilayer barriers comprising one or more barrier materials in one or more layers may be preferred for some devices. One preferred example of a multilayer barrier is a barrier comprising alternating layers of SiNₓ and a polymer, such as in the multilayer barrier SiNₓ/polymer/SiNₓ. Substantial similarity between barrier layer properties required for perovskite light emitting material, organic light emitting material and quantum dot light emitting material facilitates the combination of these light emitting materials in a single device, such as a light emitting device with multiple emissive layers.

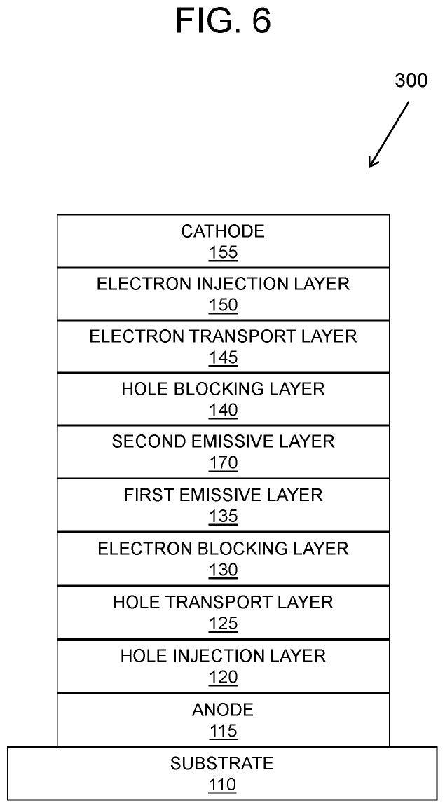

FIG. 6 shows a light emitting device 300 having two emissive layers. The light emitting device 300 may comprise one or more PeLED, OLED or QLED emissive layers. Device 300 may include a substrate 110, an anode 115, a hole injection layer 120, a hole transport layer 125, an electron blocking layer 130, a first emissive layer 135, a second emissive layer 170, a hole blocking layer 140, an electron transport layer 145, an electron injection layer 150 and a cathode 155. Device 300 may be fabricated by depositing the layers described in order. For a PeLED emissive layer, the emissive layer comprises perovskite light emitting material. For an OLED emissive layer, the emissive layer comprises organic light emitting material. For a QLED emissive layer, the emissive layer comprises quantum dot light emitting material.

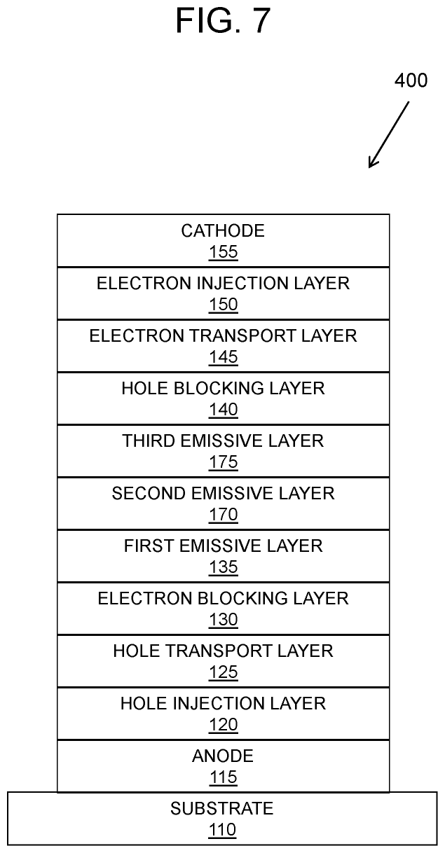

FIG. 7 shows a light emitting device 400 having three emissive layers. The light emitting device 400 may comprise one or more PeLED, OLED or QLED emissive layers. Device 400 may include a substrate 110, an anode 115, a hole injection layer 120, a hole transport layer 125, an electron blocking layer 130, a first emissive layer 135, a second emissive layer 170, a third emissive layer 175, a hole blocking layer 140, an electron transport layer 145, an electron injection layer 150 and a cathode 155. Device 400 may be fabricated by depositing the layers described in order. For a PeLED emissive layer, the emissive layer comprises perovskite light emitting material. For an OLED emissive layer, the emissive layer comprises organic light emitting material. For a QLED emissive layer, the emissive layer comprises quantum dot light emitting material.

The simple layered structures illustrated in FIGS. 6 and 7 are provided by way of non-limiting examples, and it is understood that embodiments of the invention may be used in connection with a wide variety of other structures. The specific materials and structures described are exemplary in nature, and other materials and structures may be used. Functional light emitting devices may be achieved by combining the various layers described in different ways, or layers may be omitted entirely, based on factors such as performance, design and cost. Other layers, not specifically described, may also be included. Materials other than those specifically described may be used. Although many of the examples provided herein describe various layers as comprising a single material, it is understood that combinations of materials may be used. Also, the layers may have various sublayers. The names given to the various layers herein are not intended to be strictly limiting. For example, in a device, the electron transport layer may transport electrons into the emissive layer, and also block holes from exiting the emissive layer, and may be described as an electron transport layer or a hole blocking layer.

Light emitting device architectures with multiple emissive layers, as depicted in FIGS. 6 and 7 may provide one or more advantages. Light from multiple emissive layers may be combined to enhance efficiency, lifetime and/or tune emission colour of the device. For example, multiple emission colours from multiple emissive layers may be combined within the device. For example, red light from a first emissive layer may be combined with green light from a second emissive layer and blue light from a third emissive layer to generate white light emission from the device. A multiple emissive layer device may further enable light emission from one or more perovskite light emitting materials to be combined with light emission from one or more perovskite light emitting materials, organic light emitting materials and/or quantum dot light emitting materials.

Optionally, devices fabricated in accordance with embodiments of the present invention may comprise two emissive layers. Optionally, devices fabricated in accordance with embodiments of the present invention may comprise three emissive layers. Optionally, devices fabricated in accordance with embodiments of the present invention may comprise four or more emissive layers.

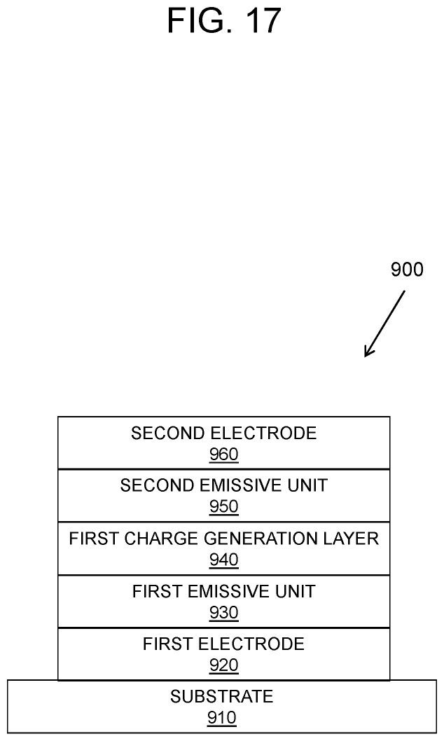

Devices fabricated in accordance with embodiments of the present invention may optionally comprise one or more charge generation layers. Optionally, a charge generation layer may be used to separate two or more emissive units within a stacked light emitting device. Stacked light emitting device 900, depicted in FIG. 17, comprises a first charge generation layer 940, which separates a first emissive unit 930 from a second emissive unit 950.

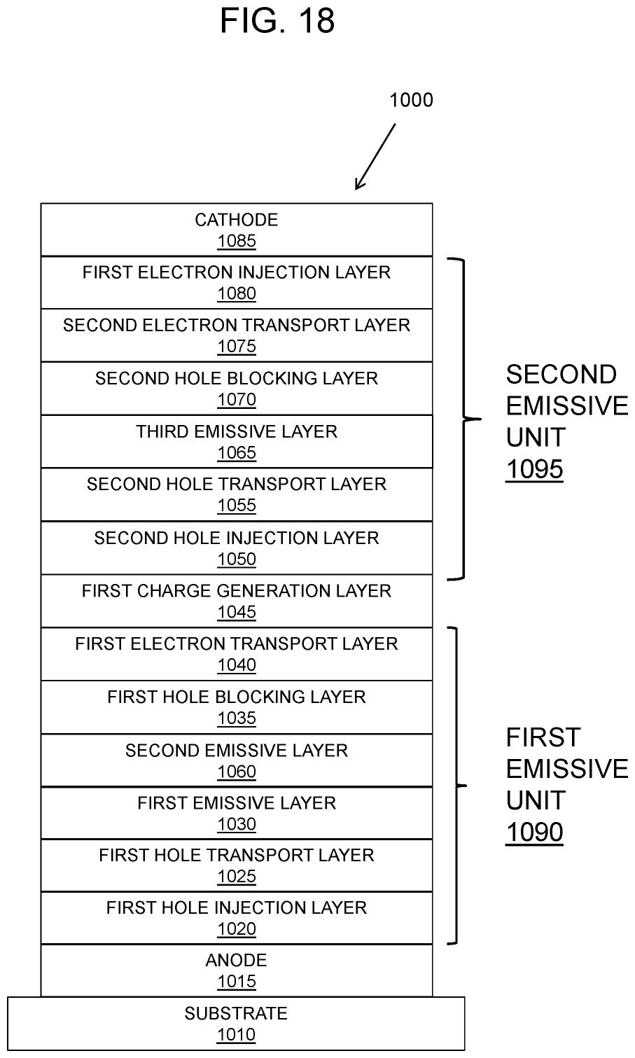

FIG. 18 shows a stacked light emitting device 1000 comprising a first emissive unit 1090 and a second emissive units 1095. The stacked light emitting device 1000 may comprise one or more PeLED, OLED or QLED emissive layers. Device 1000 may include a substrate 1010, an anode 1015, a first hole injection layer 1020, a first hole transport layer 1025, a first emissive layer 1030, a second emissive layer 1060, a first hole blocking layer 1035, a first electron transport layer 1040, a first charge generation layer 1045, a second hole injection layer 1050, a second hole transport layer 1055, a third emissive layer 1065, a second hole blocking layer 1070, a second electron transport layer 1075, a first electron injection layer 1080 and a cathode 1085. The first emissive unit 1090 comprises the first emissive layer 1030 and the second emissive layer 1060. The second emissive unit 1095 comprises the third emissive layer 1065. The first emissive layer 1030 is in contact with the second emissive layer 1060. Device 1000 may be fabricated by depositing the layers described in order. For a PeLED emissive layer, the emissive layer comprises perovskite light emitting material. For an OLED emissive layer, the emissive layer comprises organic light emitting material. For a QLED emissive layer, the emissive layer comprises quantum dot light emitting material.

A charge generation layer 940 or 1045 may comprise a single layer or multiple layers. Optionally, a charge generation layer 940 or 1045 may comprise an n-doped layer for the injection of electrons, and a p-doped layer for the injection of holes. Optionally, a charge generation layer 940 or 1045 may include a hole injection layer (HIL). Optionally, a p-doped layer of charge generation layer 940 may function as a hole injection layer (HIL). FIG. 18 depicts a stacked light emitting device 1000 having two emissive units, wherein a first charge generation layer 1045 is adjacent to and in contact with a second hole injection layer 1050. Optionally, a charge generation layer 940 or 1045 may include a hole injection layer.

Optionally, a charge generation layer 940 or 1045 may include an electron injection layer (EIL). Optionally, an n-doped layer of charge generation layer 940 or 1045 may function as an electron injection layer (EIL). FIG. 18 depicts a stacked light emitting device 1000 having two emissive units, wherein a first charge generation layer 1045 includes an electron injection layer. Optionally, a charge generation layer 940 or 1045 may be positioned adjacent to and in contact with a separate electron injection layer.

A charge generation layer 940 or 1045 may be deposited by a solution process or by a vacuum deposition process. A charge generation layer 940 or 1045 may be composed of any applicable materials that enable injection of electrons and holes. A charge generation layer 940 or 1045 may be doped or undoped. Doping may be used to enhance conductivity.

One example of vapour process charge generation layer is a dual layer structure consisting of lithium doped BPhen (Li-BPhen) as the n-doped layer for electron injection, in combination with of 1,4,5,8,9,11-Hexaazatriphenylenehexacarbonitrile (HATCN) as the p-doped layer for hole injection. One example of a solution process charge generation layer is a dual layer structure consisting of polyethylenimine (PEI) surface modified zinc oxide (ZnO) as the n-doped layer for electron injection, in combination with molybdenum oxide (MoO₃) or tungsten trioxide (WO₃) as the p-doped layer for hole injection. Other materials or combinations of materials may be used for charge generation layers. Depending on the configuration of a particular device, charge generation layers may be disposed at locations different than those shown in device 900 and device 1000. The preceding examples of charge generation layer materials are all especially well-suited to application in PeLEDs. However, these materials may also be implemented effectively in OLEDs and QLEDs. Substantial similarity between charge generation layer properties required for perovskite light emitting material, organic light emitting material and quantum dot light emitting material facilitates the combination of these light emitting materials in a single device, such as a light emitting device with multiple emissive layers.

Optionally, one or more charge generation layers within a stacked light emitting device may or may not be directly connected to one or more external electrical sources, and therefore may or may not be individually addressable. Connecting one or more charge generation layers to one or more external sources may be of advantage in that light emission from separate emissive units may be separately controlled, allowing the brightness and/or colour of a stacked light emitting device with multiple emissive units to be tuned according to the needs of the application.

Optionally, devices fabricated in accordance with embodiments of the present invention may be stacked light emitting devices. Optionally, devices fabricated in accordance with embodiments of the present invention may comprise two or more emissive units separated by one or more charge generation layers. Optionally, the two or more emissive units and one or more charge generation layers may be vertically stacked within the device.

One example of how a stacked light emitting device comprising multiple emissive units and multiple emissive layers may be used is in a device that emits white light for application in a display or a light panel. Referring to device 1000 in FIG. 18, in one embodiment, the first emissive unit 1090 may comprise a first emissive layer 1030 and a second emissive layer 1060, wherein the first emissive layer 1030 and the second emissive layer 1060 are in contact. The second emissive unit 1095 may comprise a third emissive layer 1065. The first emissive layer 1030 may emit red light. The second emissive layer 1060 may emit green light. The third emissive layer 1065 may emit blue light. Light from the multiple emissive layers may be combined to generate white light emission from the device. Perovskite light emitting material may be used in the emissive layers that emit red light and green light. Organic light emitting material may be used in the emissive layer that emits blue light. The simple example described herein with reference to FIG. 18 is provided by way of a non-limiting example, and it is understood that embodiments of the invention may be used in connection with a wide variety of other structures. The specific emission colours and combinations of emissive layers are exemplary in nature, and other emission colours and emissive layer combinations may be used.

Unless otherwise specified, any one of the layers of the various embodiments may be deposited by any suitable method. Methods include vacuum thermal evaporation, sputtering, electron beam physical vapour deposition, organic vapor phase deposition and organic vapour jet printing. Other suitable methods include spincoating and other solution-based processes. Substantially similar processes can be used to deposit materials used in PeLED, OLED and QLED devices, which facilitates the combination of these materials in a single device, such as a light emitting device with multiple emissive layers.

Devices fabricated in accordance with embodiments of the invention may be incorporated into a wide range of consumer products. Optionally, devices may be used in displays for televisions, computer monitors, tablets, laptop computers, smart phones, cell phones, digital cameras, video recorders, smartwatches, fitness trackers, personal digital assistants, vehicle displays and other electronic devices. Optionally, devices may be used for micro-displays or heads-up displays. Optionally, devices may be used in light panels for interior or exterior illumination and/or signaling, in smart packaging or in billboards.

Optionally, various control mechanisms may be used to control light emitting devices fabricated in accordance with the present invention, including passive matrix and active matrix address schemes.

The materials and structures described herein may have applications in devices other than light emitting devices. For example, other optoelectronic devices such as solar cells, photodetectors, transistors or lasers may employ the materials and structures.

Layers, materials, regions, units and devices may be described herein in reference to the colour of light they emit. As used herein, a “red” layer, material, region, unit or device, refers to one that emits light that has an emission spectrum with a peak wavelength in the range of about 580-780 nm; a “green” layer, material, region, unit or device, refers to one that emits light that has an emission spectrum with a peak wavelength in the range of about 500-580 nm; a “blue” layer, material, region, unit or device, refers to one that emits light that has an emission spectrum with a peak wavelength in the range of about 380-500 nm. Preferred ranges include a peak wavelength in the range of about 600-640 nm for red, about 510-550 nm for green, and about 440-465 nm for blue. As used herein, a “yellow” emissive layer, material, region unit or device refers to one that emits light with a substantial proportion of both red and green light in the emissive spectrum. As used herein, a “cyan” emissive layer, material, region unit or device refers to one that emits light with a substantial proportion of both green and blue light in the emissive spectrum. As used herein, a “magenta” emissive layer, material, region unit or device refers to one that emits light with a substantial proportion of both red and blue light in the emissive spectrum.

Similarly, any reference to a colour altering layer refers to a layer that converts or modifies another colour of light to light having a wavelength as specified for that colour. For example, a “red” color filter refers to a filter that results in light having an emission spectrum with a peak wavelength in the range of about 580-780 nm. In general, there are two classes of colour altering layers: colour filters that modify a spectrum by removing unwanted wavelengths of light, and colour changing layers that convert photons of higher energy to photons of lower energy.

Display technology is rapidly evolving, with recent innovations enabling thinner and lighter displays with higher resolution, improved frame rate and enhanced contrast ratio. However, one area where significant improvement is still required is colour gamut. Digital displays are currently incapable of producing many of the colours the average person experiences in day-to-day life. To unify and guide the industry towards improved colour gamut, two industry standards have been defined, DCI-P3 and Rec. 2020, with DCI-P3 often seen as a stepping stone towards Rec. 2020.

DCI-P3 was defined by the Digital Cinema Initiatives (DCI) organization and published by the Society of Motion Picture and Television Engineers (SMPTE). Rec. 2020 (more formally known as ITU-R Recommendation BT. 2020) was developed by the International Telecommunication Union to set targets, including improved colour gamut, for various aspects of ultra-high-definition televisions.

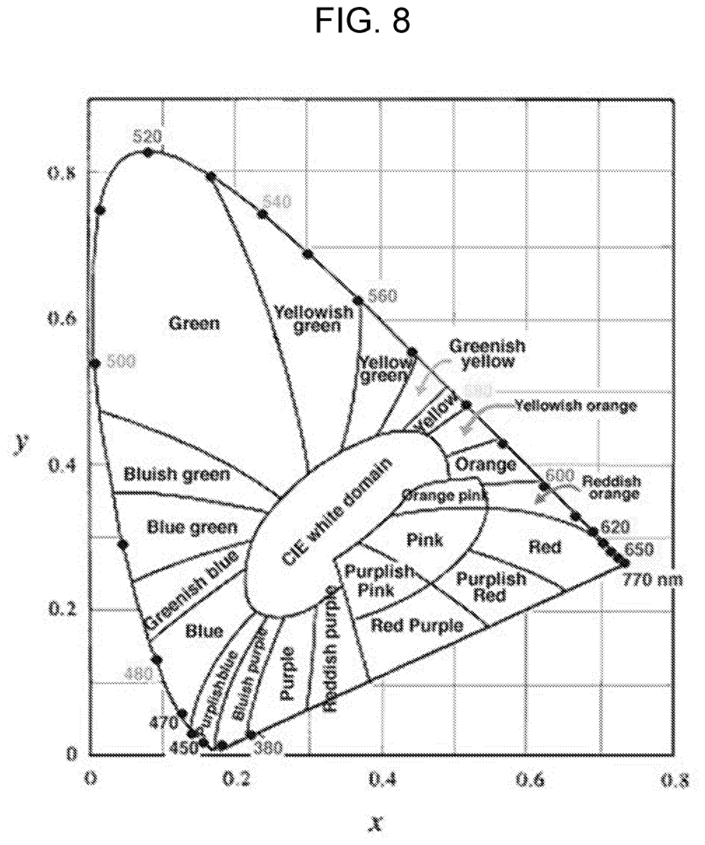

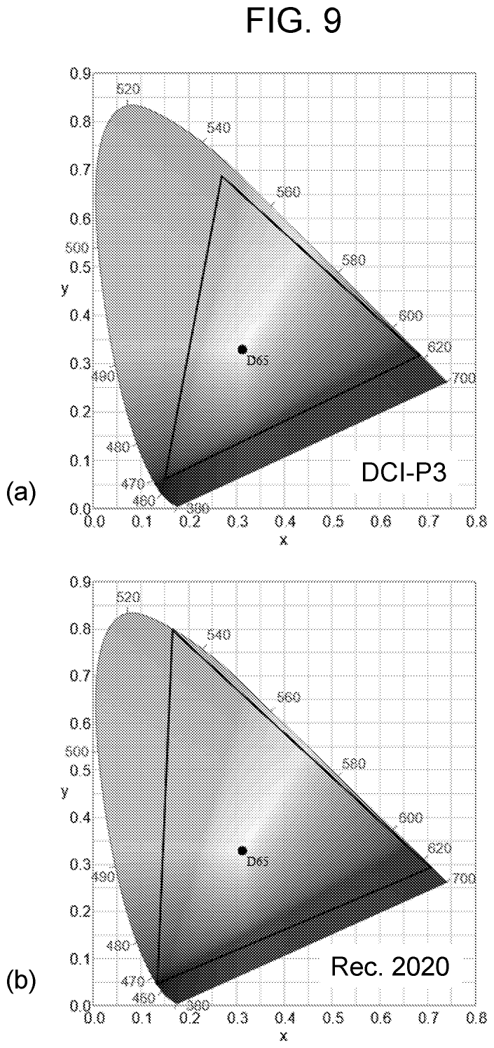

The CIE 1931 (x, y) chromaticity diagram was created by the Commission Internationale de l′Éclairage (CIE) in 1931 to define all colour sensations that an average person can experience. Mathematical relationships describe the location of each colour within the chromaticity diagram. The CIE 1931 (x, y) chromaticity diagram may be used to quantify the colour gamut of displays. The white point (D65) is at the centre, while colours become increasingly saturated (deeper) towards the extremities of the diagram. FIG. 8 shows the CIE 1931 (x, y) chromaticity diagram with labels added to different locations on the diagram to enable a general understanding of distribution of colour within the colour space. FIG. 9 shows (a) DCI-P3 and (b) Rec. 2020 colour spaces superimposed on the CIE 1931 (x, y) chromaticity diagram. The tips of the triangles are primary colours for DCI-P3 and Rec. 2020, respectively, while colours enclosed within the triangles are all the colours that can be reproduced by combining these primary colours. For a display to meet DCI-P3 colour gamut specifications, the red, green and blue sub-pixels of the display must emit light at least as deep in colour as the DCI-P3 primary colours. For a display to meet Rec. 2020 colour gamut specifications, the red, green and blue sub-pixels of the display must emit light at least as deep in colour as the Rec. 2020 primary colours. Primary colours for Rec. 2020 are significantly deeper than for DCI-P3, and therefore achievement of the Rec. 2020 standard for colour gamut is seen as a greater technical challenge than achieving the DCI-P3 standard.

OLED displays can successfully render the DCI-P3 colour gamut. For example, smartphones with OLED displays such as the iPhone X (Apple), Galaxy S9 (Samsung) and OnePlus 5 (OnePlus) can all render the DCI-P3 gamut. Commercial liquid crystal displays (LCDs) can also successfully render the DCI-P3 colour gamut. For example, LCDs in the Surface Studio (Microsoft), Mac Book Pro and iMac Pro (both Apple) can all render the DCI-P3 gamut. In addition, electroluminescent and photoluminescent quantum dot technology has also been used to demonstrate electroluminescent and photoluminescent QLED displays with wide colour gamut. However, until now, no display has been demonstrated that can render the Rec. 2020 colour gamut.

Here we disclose a novel light emitting device architecture including one or more perovskite light emitting materials and two or more emissive layers. In various embodiments, when implemented in a sub-pixel of a display, the light emitting device architecture can enable the sub-pixel to render a primary colour of the DCI-P3 colour gamut. In various embodiments, when implemented in a sub-pixel of a display, the light emitting device architecture can enable the sub-pixel to render a primary colour of the Rec. 2020 colour gamut. In various embodiments, the light emitting device architecture may further include a microcavity structure to further enhance the colour saturation of the device. In various embodiments, the light emitting device architecture may further include a colour altering layer to further enhance the colour saturation of the device.

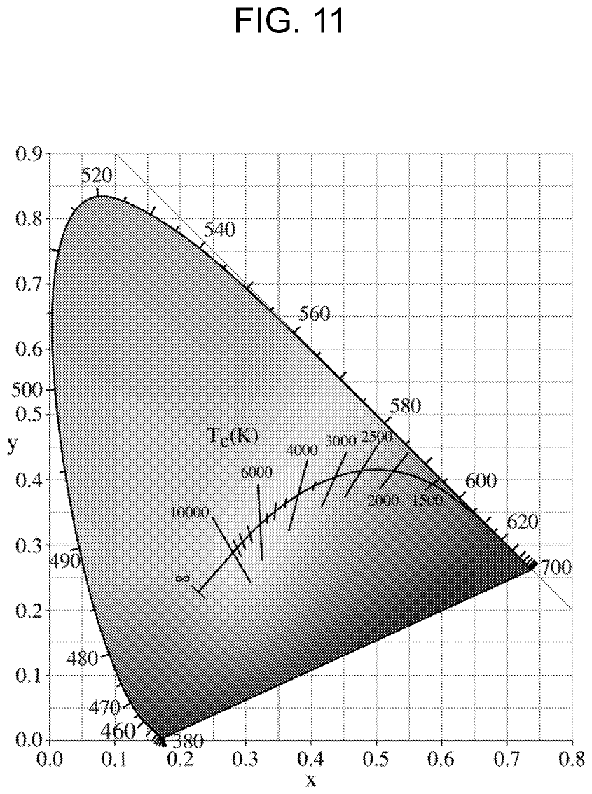

Layers, materials, regions, units and devices may be described herein in reference to the colour of light they emit. As used herein, a “white” layer, material, region, unit or device, refers to one that emits light with chromaticity coordinates that are approximately located on the Planckian Locus. The Planckian Locus is the path or locus that the colour of an incandescent blackbody would take in a particular chromaticity space as the blackbody temperature changes. FIG. 11 depicts a rendition of the CIE 1931 (x, y) color space chromaticity diagram that also shows the Planckian Locus. How closely the chromaticity of light matches the Planckian Locus can be quantified in terms of Duv=√(Δu′²+Δv′²), which is the distance in the CIE 1976 (u′, v′) color space of the light emitting device chromaticity from the Planckian Locus. The CIE 1976 (u′, v′) color space is used in preference over the CIE 1931 (x, y) color space because in the CIE 1976 (u′, v′) color space, distance is approximately proportional to perceived difference in color. The conversion is very simple: u′=4x/(−2x+12y+3) and v′=9y/(−2x+12y+3). As used herein, a “white” layer, material, region, unit or device, refers to one that emits light with CIE 1976 (u′, v′) chromaticity coordinates having Duv less than or equal to 0.010.

Further metrics that can be used to quantify “white” light include correlated colour temperature (CCT), which is the temperature of an ideal blackbody radiator that radiates light of a colour comparable to that of the light source. Preferably, a “white” light source for lighting applications should have CCT in the approximate range of 2700K to 6500K. More preferably, a “white” light source should have CCT in the approximate range of 3000K to 5000K. Preferably, a “white” light source for display applications should have CCT of approximately 6504K.

Further metrics that can be used to quantify “white” light include colour rendering index (CRI), which is a quantitative measure of the ability of a light source to render the colours of various objects accurately in comparison with an ideal or natural light source. A higher CRI value generally corresponds to a light source being able to render colours more accurately, with 100 being the theoretical maximum value for CRI. Preferably, a “white” light source should have CRI greater than or equal to 80. More preferably, a “white” light source should have CRI greater than or equal to 90.

The advantages of organic light emitting devices with multiple emissive layers are well known in the art. Examples of organic light emitting devices with multiple emissive layers are described in United States patent U.S. Pat. No. 8,564,001 B2, Andrade et al. and Adamovich et al. All of these citations are included herein by reference in their entirety. United States patent U.S. Pat. No. 8,654,001 B2 describes an organic light emitting device architecture for use in a light panel, wherein the device emits white light and comprises a single emissive unit with two emissive layers. Andrade et al. describes various organic light emitting device architectures for use in a light panel, including a device that emits white light and comprises a single emissive unit with three emissive layers. Adamovich et al. describes a stacked organic light emitting device architecture for use in a display or light panel, wherein the stacked device emits white light and comprises two emissive units, wherein each emissive unit comprises two emissive layers.

Although the performance advantages of light emitting devices with multiple emissive layers are known in relation to organic light emitting material, until now, no light emitting device with multiple emissive layers has been demonstrated that comprises perovskite light emitting material. We demonstrate that various additional performance advantages can be realized by including at least one perovskite light emitting material in one or more emissive layers of a light emitting device with multiple emissive layers.

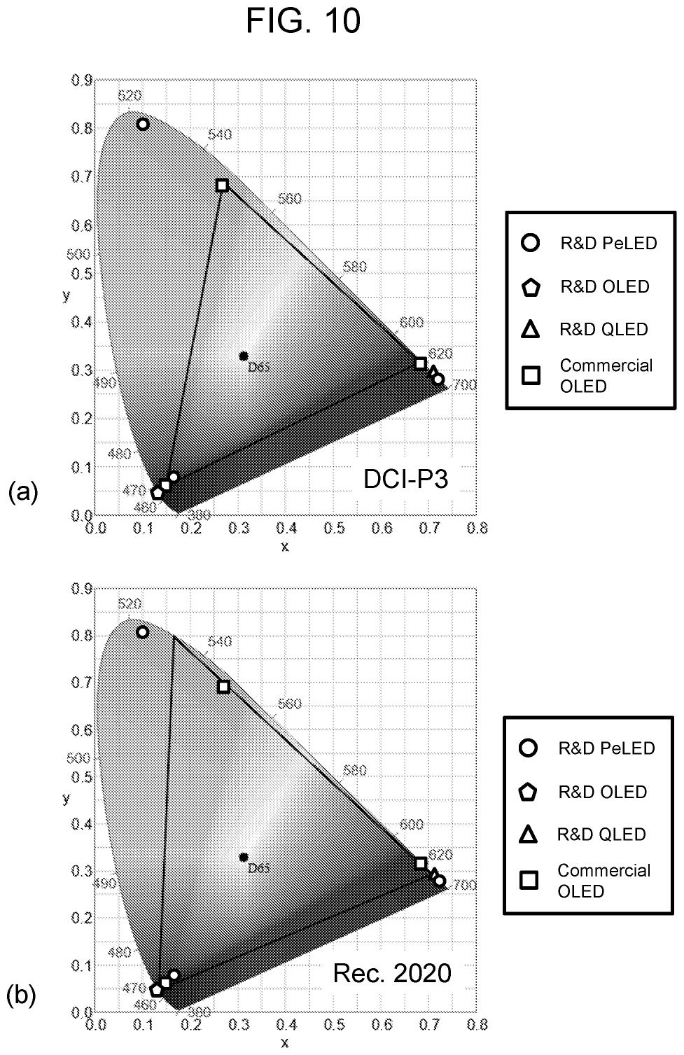

One or more advantages of including at least one perovskite light emitting material in at least one emissive layer of a light emitting device with multiple emissive layers may be demonstrated using the data shown in Table 1 and FIG. 10. The data in Table 1 and FIG. 10 may also be used to demonstrate one or more advantages of combining one or more emissive layers including perovskite light emitting material with one or more emissive layers including organic light emitting material and/or quantum dot light emitting material in a light emitting device with multiple emissive layers.

Table 1 shows CIE 1931 (x, y) colour coordinates for single emissive layer red, green and blue PeLED, OLED and QLED devices. Also included in Table 1 are CIE 1931 (x, y) colour coordinates for DCI-P3 and Rec. 2020 colour gamut standards. Generally, for red light, a higher CIE x value corresponds to deeper emission colour, for green light, a higher CIE y value corresponds to deeper emission colour, and for blue light, a lower CIE y value corresponds to deeper emission colour. This can be understood with reference FIG. 10, which includes markers for the red, green and blue R&D PeLED (circles), blue R&D OLED (pentagon), red R&D QLED (triangles) and Commercial OLED (squares) device data in Table 1, as well as markers for the primary colours of the DCI-P3 colour gamut in FIG. 10a and for the Rec. 2020 colour gamut in FIG. 10b.

TABLE 1
CIE 1931 (x, y) colour coordinates for exemplary single emissive
layer PeLED, OLED and QLED devices. Also included are colour
coordinates for DCI-P3 and Rec. 2020 colour gamut standards.

| | Red | | Green | | Blue | |
|---|---|---|---|---|---|---|
| | CIE x | CIE y | CIE x | CIE y | CIE x | CIE y |
| DCI-P3 | 0.680 | 0.320 | 0.265 | 0.690 | 0.150 | 0.060 |
| Rec. 2020 | 0.708 | 0.292 | 0.170 | 0.797 | 0.131 | 0.046 |
| Commercial | 0.680 | 0.320 | 0.265 | 0.690 | 0.150 | 0.060 |
| OLED | | | | | | |
| R&D PeLED | 0.720 | 0.280 | 0.100 | 0.810 | 0.166 | 0.079 |
| R&D OLED | — | — | — | — | 0.146 | 0.045 |
| R&D QLED | 0.712 | 0.288 | — | — | — | — |

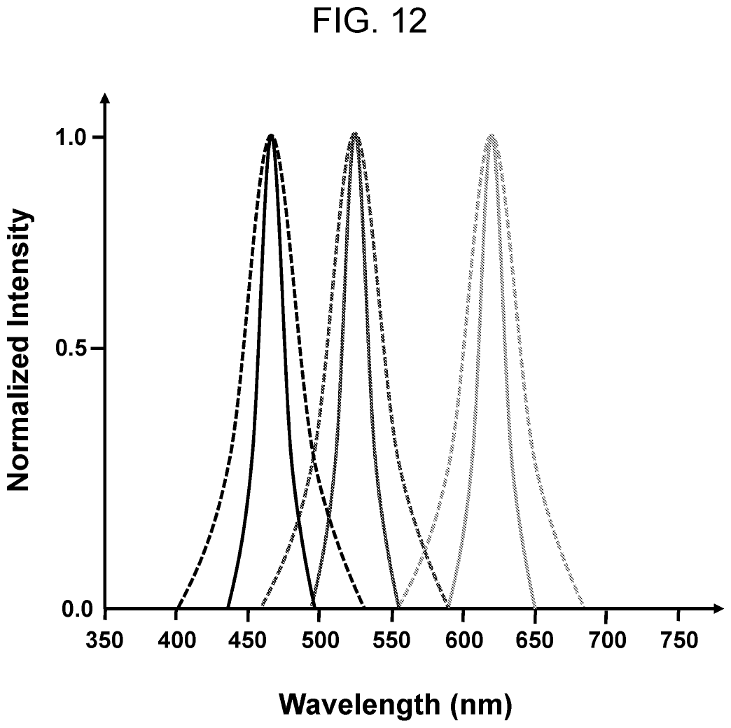

FIG. 12 depicts exemplary electroluminescence emission spectra for single emissive layer red, green and blue PeLEDs, OLEDs and QLEDs. The red, green and blue spectra depicted using dashed lines correspond to spectra for Commercial OLED devices, such as those in the Apple iPhone X, which may be used to render the DCI-P3 colour gamut. The red spectrum depicted using a solid line corresponds to the spectrum for a red light emitting R&D PeLED device with a single emissive layer. The green spectrum depicted using a solid line corresponds to the spectrum for a green light emitting R&D PeLED device with a single emissive layer. The blue spectrum depicted using a solid line corresponds to the spectrum for a blue light emitting R&D OLED device with a single emissive layer. It can be seen from FIG. 12 that as an emission spectrum narrows, emission colour becomes more saturated. Electroluminescence spectra depicted using solid lines in FIG. 12 correspond to light emitting devices that may be used to render the Rec. 2020 colour gamut.

The CIE 1931 (x, y) colour coordinate data reported for single emissive layer red, green and blue PeLED, OLED and QLED devices in Table 1 are exemplary. Commercial OLED data are taken from the Apple iPhone X, which fully supports the DCI-P3 colour gamut. This data set is available from Raymond Soneira at DisplayMate Technologies Corporation (Soneira et al.). Data for R&D PeLED, R&D OLED and R&D QLED devices are taken from a selection of peer-reviewed scientific journals: Red R&D PeLED data are taken from Wang et al. Red R&D QLED data are taken from Kathirgamanathan et al. (2). Green R&D PeLED data are taken from Hirose et al. Blue R&D PeLED data are taken from Kumar et al. Blue R&D OLED data are taken from Takita et al. Data from these sources are used by way of example, and should be considered non-limiting. Data from other peer-reviewed scientific journals, simulated data and/or experimental data collected from laboratory devices may also be used to demonstrate the aforementioned advantages of the claimed light emitting device with multiple emissive layers.

As can be seen from Table 1 and FIG. 10a, existing organic light emitting materials and devices can already be used to demonstrate a commercial display that can render the DCI-P3 colour gamut, as is exemplified by the Apple iPhone X. However, as can be seen from FIG. 10b, existing organic light emitting materials and devices alone cannot be used to demonstrate a display that can render the Rec. 2020 colour gamut. Table 1 and FIG. 10b show that one path to demonstrating a display that can render the Rec. 2020 colour gamut is to include one or more perovskite emissive layers in one or more devices in one or more sub-pixels of a display.

Optionally, by including one or more perovskite light emitting materials in a light emitting device with multiple emissive layers, one or more emissive layers of the device may emit red light with CIE 1931 (x, y)=(0.720, 0.280), which as can be seen from FIG. 10b, is more saturated than the red primary color for the Rec. 2020 standard, which has CIE 1931 (x, y)=(0.708, 0.292).

Optionally, by including one or more perovskite light emitting materials in a light emitting device with multiple emissive layers, one or more emissive layers may emit green light with CIE 1931 (x, y)=(0.100, 0.810), which as can be seen from FIG. 10b, is more saturated than the green primary colour for the Rec. 2020 standard, which has CIE 1931 (x, y)=(0.170, 0.797).

Furthermore, in this invention, we propose that it may be advantageous under some circumstances to combine one or more emissive layers comprising perovskite light emitting material with one or more emissive layers comprising quantum dot light emitting material. Optionally, by including one or more quantum dot light emitting materials in a light emitting device, one or more emissive layers of the device may emit red light with CIE 1931 (x, y)=(0.712, 0.288), which as can be seen from FIG. 10b, is more saturated than the red primary color for the Rec. 2020 standard, which has CIE 1931 (x, y)=(0.708, 0.292).

Furthermore, in this invention, we propose that it may be advantageous under some circumstances to combine one or more emissive layers comprising perovskite light emitting material with one or more emissive layers comprising organic light emitting material. Optionally, by including one or more organic light emitting materials in a light emitting device, one or more emissive layers of the device may emit blue light with CIE 1931 (x, y)=(0.146, 0.045), which as can be seen from FIG. 10b, is more saturated than the blue primary color for the Rec. 2020 standard, which has CIE 1931 (x, y)=(0.131, 0.046).

As described herein, the colour saturation of blue light emission from exemplary emissive layers comprising perovskite blue light emitting material may be slightly less than that of blue light emission from exemplary emissive layers comprising organic blue light emitting material. For example, as shown in Table 1, a perovskite blue light emitting material may emit light with CIE 1931 (x, y)=(0.166, 0.079), which as can be seen from FIG. 10b, is less saturated than the blue primary color for the Rec. 2020 standard, which has CIE 1931 (x, y)=(0.131, 0.046). However, under some circumstances, including perovskite blue light emitting material may provide the device with one or more advantages, such as improved efficiency, higher brightness, improved operational lifetime, lower voltage and/or reduced cost, and may therefore be preferred.

Optionally, by including one or more perovskite light emitting materials in a light emitting device with multiple emissive layers, the device may emit white light. Optionally, white light emission may be demonstrated using a light emitting device comprising a first emissive layer and a second emissive layer, wherein at least one emissive layer comprises a yellow light emitting material, and at least one emissive layer comprises a blue light emitting material. White light emission may be demonstrated by combining yellow and blue light emission from the respective emissive layers.

Optionally, the yellow light emitting material may be a perovskite light emitting material, and the blue light emitting material may be a perovskite light emitting material, an organic light emitting material or a quantum dot light emitting material. Optionally, the yellow light emitting material may be a perovskite light emitting material, an organic light emitting material or a quantum dot light emitting material, and the blue light emitting material may be a perovskite light emitting material. Optionally, the yellow light emitting material may be a perovskite light emitting material and the blue light emitting material may be a perovskite light emitting material. Optionally, the yellow light emitting material may be a perovskite light emitting material and the blue light emitting material may be an organic light emitting material. The inclusion of an organic blue light emitting material may be preferred because such a material may enable the device to demonstrate longer operational lifetime and deeper colour saturation.

Optionally, white light emission may be demonstrated using a light emitting device comprising a first emissive layer, a second emissive layer and a third emissive layer, wherein at least one emissive layer comprises a red light emitting material, at least one emissive layer comprises a green light emitting material, and at least one emissive layer comprises a blue light emitting material. White light emission may be demonstrated by combining red, green and blue light emission from the respective emissive layers.

Optionally, the red light emitting material may be a perovskite light emitting material, the green light emitting material may be a perovskite light emitting material, an organic light emitting material or a quantum dot light emitting material, and the blue light emitting material may be a perovskite light emitting material, an organic light emitting material or a quantum dot light emitting material. Optionally, the red light emitting material may be a perovskite light emitting material, an organic light emitting material or a quantum dot light emitting material, the green light emitting material may be a perovskite light emitting material, and the blue light emitting material may be a perovskite light emitting material, an organic light emitting material or a quantum dot light emitting material. Optionally, the red light emitting material may be a perovskite light emitting material, an organic light emitting material or a quantum dot light emitting material, the green light emitting material may be a perovskite light emitting material, an organic light emitting material or a quantum dot light emitting material, and the blue light emitting material may be a perovskite light emitting material. Optionally, the red light emitting material may be a perovskite light emitting material, the green light emitting material may be a perovskite light emitting material and the blue light emitting material may be a perovskite light emitting material. Optionally, the red light emitting material may be a perovskite light emitting material, the green light emitting material may be a perovskite light emitting material and the blue light emitting material may be an organic light emitting material. The inclusion of an organic blue light emitting material may be preferred because such a material may enable the device to demonstrate longer operational lifetime and deeper colour saturation.

Such white light emitting devices comprising one or more perovskite light emitting materials may be advantageous because the higher colour saturation may enable white light emission with higher colour rendering index (CRI) than for equivalent devices comprising only organic light emitting material or quantum dot light emitting material. For example, the device may be able to render saturated colours with improved fidelity. This may be advantageous for application in a light panel. For example, such a light emitting device may enable white light emission with CRI greater than or equal to 80, and optionally greater than or equal to 90.

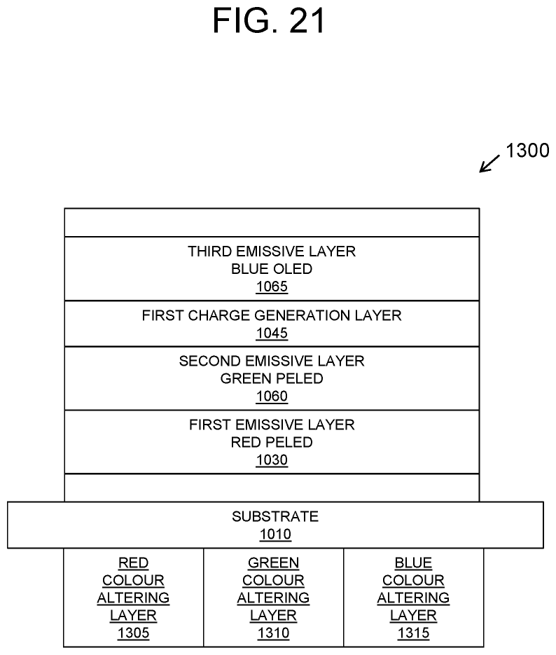

Such white light emitting devices comprising one or more perovskite light emitting materials may be advantageous because the higher colour saturation and narrower emission spectra of perovskite light emitting materials, as shown in FIG. 12, of perovskite light emitting materials may enable the device to be optically coupled to one or more colour altering layers more efficiently than for equivalent devices comprising only organic light emitting material or quantum dot light emitting material. This may be advantageous for application in a display. An example embodiment is depicted in FIG. 21 for a bottom-emission stacked light emitting device 1300 comprising a substrate 1010, a first emissive layer 1030 comprising a red perovskite light emitting material, a second emissive layer 1060 comprising a green perovskite light emitting material, and a third emissive layer 1065 comprising a blue organic light emitting material. The first emissive layer 1030 is in contact with the second emissive layer 1060. A first charge generation layer 1045 is disposed between the second emissive layer 1060 and the third emissive layer 1065. Without the application of any optional colour altering layers, stacked light emitting device 1300 would emit white light.

Optionally, by optically coupling a red colour altering layer 1305 to white light emitting device 1300, the light emitting device 1300 may emit red light that may render the red primary colour of the DCI-P3 colour gamut. In one embodiment, the light emitting device 1300 may emit red light with CIE 1931 x coordinate greater than or equal to 0.680. Optionally, the light emitting device 1300 may emit red light that may render the red primary colour of the Rec. 2020 colour gamut. In one embodiment, the light emitting device 1300 may emit red light with CIE 1931 x coordinate greater than or equal to 0.708. Optionally, the red colour altering layer may be a red colour filter.

Optionally, by optically coupling a green colour altering layer 1310 to a white light emitting device 1300, the light emitting device 1300 may emit green light that may render the green primary colour of the DCI-P3 colour gamut. In one embodiment, the light emitting device 1300 may emit green light with CIE 1931 y coordinate greater than or equal to 0.690. Optionally, the light emitting device 1300 may emit green light that may render the green primary colour of the Rec. 2020 colour gamut. In one embodiment, the light emitting device 1300 may emit green light with CIE 1931 y coordinate greater than or equal to 0.797. Optionally, the green colour altering layer may be a green colour filter.

Optionally, by optically coupling a blue colour altering layer 1315 to a white light emitting device 1300, the light emitting device 1300 may emit blue light that may render the blue primary colour of the DCI-P3 colour gamut. In one embodiment, the light emitting device 1300 may emit blue light with CIE 1931 y coordinate less than or equal to 0.060. Optionally, the light emitting device 1300 may emit blue light that may render the blue primary colour of the Rec. 2020 colour gamut. In one embodiment, the light emitting device 1300 may emit blue light with CIE 1931 y coordinate less than or equal to 0.046. Optionally, the blue colour altering layer may be a blue colour filter.

By optically coupling such red, green and blue colour altering layers 1305, 1310 and 1315 to such a white light emitting device 1300, a display may be demonstrated that may fulfill colour gamut requirements of the DCI-P3 display standard, and optionally of the Rec. 2020 colour gamut. This may enable the display to render a broader range of colours experienced in everyday life, thereby improving functionality and user experience.

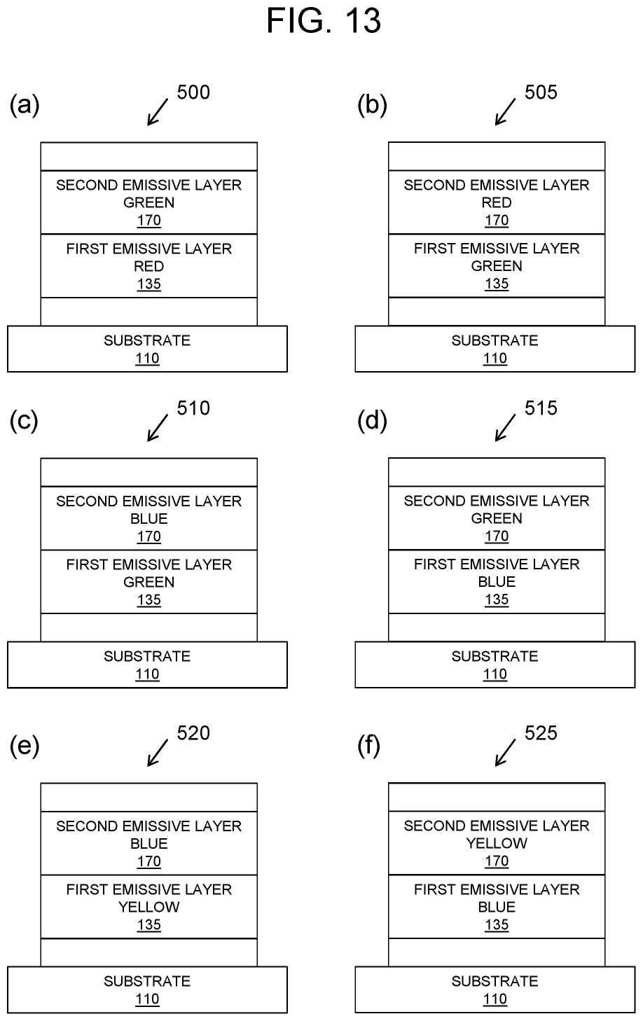

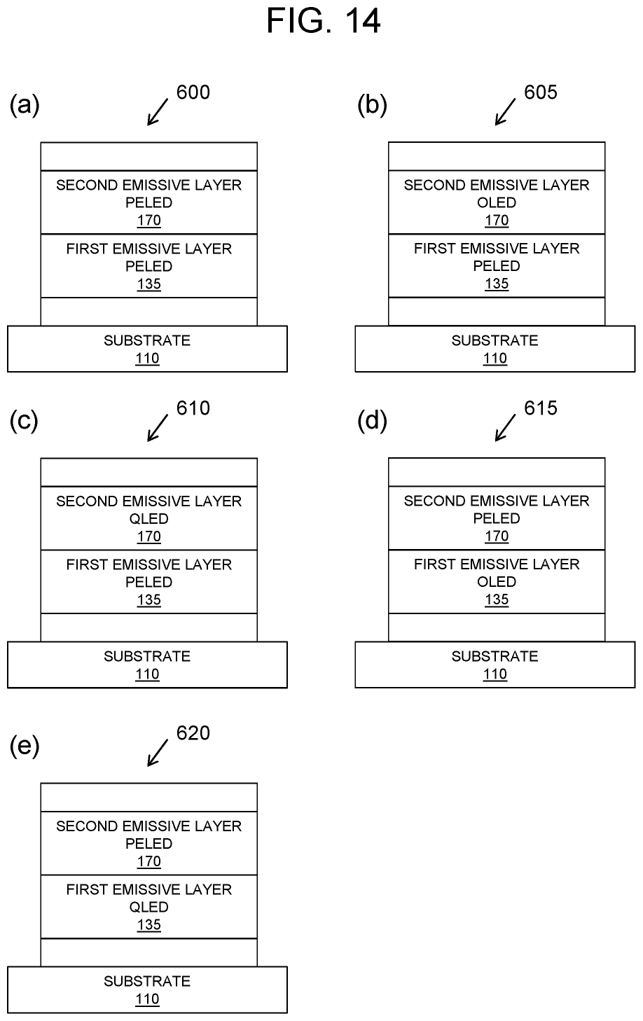

FIGS. 13 and 14 depict various configurations of emissive layers for a light emitting device having two emissive layers. In each configuration, the light emitting device comprises a substrate 110, a first emissive layer 135 and a second emissive layer 170. The first emissive layer 135 is disposed over the first electrode (not shown). The second emissive layer 170 is disposed over the first emissive layer 135. The second electrode (not shown) is disposed over the second emissive layer 170. The first emissive layer 135 is in contact with the second emissive layer 170. Various additional layers may be disposed between the first electrode and the first emissive layer 135. Various additional layers may be disposed between the second emissive layer 170 and the second electrode. In each configuration, the light emitting device comprises at least one emissive layer that comprises perovskite light emitting material. In each configuration, the light emitting device further comprises at least one further emissive layer that comprises perovskite light emitting material, organic light emitting material or quantum dot light emitting material. Such a light emitting device architecture may be advantageous because the combination of different light emitting materials may enable the optimum type of light emitting material to be selected for each emissive layer, thereby enhancing performance beyond that which could be achieved by a light emitting device comprising only a single type of light emitting material, such as only perovskite light emitting material, only organic light emitting material or only quantum dot light emitting material. For example, a broader range of emission colours may be enabled and the colour gamut, electroluminescence efficiency and/or electroluminescence stability of the device may be enhanced.

FIG. 13 depicts various configurations of emissive layers that emit different colours of light for a light emitting device having two emissive layers.

In one embodiment, the first emissive layer 135 may comprise a red light emitting material, and the second emissive layer 170 may comprise a green light emitting material. This embodiment is depicted by light emitting device 500 in FIG. 13a.

In one embodiment, the first emissive layer 135 may comprise a green light emitting material, and the second emissive layer 170 may comprise a red light emitting material. This embodiment is depicted by light emitting device 505 in FIG. 13b.

In one embodiment, the first emissive layer 135 may comprise a red light emitting material, and the second emissive layer 170 may comprise a blue light emitting material.

In one embodiment, the first emissive layer 135 may comprise a blue light emitting material, and the second emissive layer 170 may comprise a red light emitting material.

In one embodiment, the first emissive layer 135 may comprise a green light emitting material, and the second emissive layer 170 may comprise a blue light emitting material. This embodiment is depicted by light emitting device 510 in FIG. 13c.

In one embodiment, the first emissive layer 135 may comprise a blue light emitting material, and the second emissive layer 170 may comprise a green light emitting material. This embodiment is depicted by light emitting device 515 in FIG. 13d.

In one embodiment, the first emissive layer 135 may comprise a yellow light emitting material, and the second emissive layer 170 may comprise a blue light emitting material. This embodiment is depicted by light emitting device 520 in FIG. 13e.

In one embodiment, the first emissive layer 135 may comprise a blue light emitting material, and the second emissive layer 170 may comprise a yellow light emitting material. This embodiment is depicted by light emitting device 525 in FIG. 13f.

In one embodiment, the first emissive layer 135 may comprise a green light emitting material, and the second emissive layer 170 may comprise a yellow light emitting material.

In one embodiment, the first emissive layer 135 may comprise a yellow light emitting material, and the second emissive layer 170 may comprise a green light emitting material.

In one embodiment, the first emissive layer 135 may comprise a red light emitting material, and the second emissive layer 170 may comprise a yellow light emitting material.

In one embodiment, the first emissive layer 135 may comprise a yellow light emitting material, and the second emissive layer 170 may comprise a red light emitting material.

FIG. 14 depicts various configurations of emissive layers comprising various different types of light emitting material for a light emitting device having two emissive layers. For simplicity, in FIG. 14, an emissive layer comprising perovskite light emitting material is labelled “PELED”, an emissive layer comprising organic light emitting material is labelled “OLED”, and an emissive layer comprising quantum dot light emitting material is labelled “QLED”.

In one embodiment, the first emissive layer 135 may comprise a perovskite light emitting material, and the second emissive layer 170 may comprise a perovskite light emitting material, an organic light emitting material or quantum dot light emitting material.

In one embodiment, the first emissive layer 135 may comprise a perovskite light emitting material, an organic light emitting material or quantum dot light emitting material, and the second emissive layer 170 may comprise a perovskite light emitting material.

In one embodiment, the at least one further emissive layer may comprises a perovskite light emitting material or an organic light emitting material. This embodiment is depicted by light emitting devices 600 in FIG. 14a, 605 in FIGS. 14b and 615 in FIG. 14d.

In one embodiment, the first emissive layer 135 may comprise a perovskite light emitting material, and the second emissive layer 170 may comprise a perovskite light emitting material. This embodiment is depicted by light emitting device 600 in FIG. 14a. Such a device architecture may be advantageous in that the manufacturing process may be simplified for a light emitting device comprising only PeLED emissive layers.

In one embodiment, the at least one further emissive layer may comprise an organic light emitting material. This embodiment is depicted by light emitting devices 605 in FIGS. 14b and 615 in FIG. 14d. Such device architectures may be advantageous because a perovskite light emitting material may be preferred for at least one emissive layer of a light emitting device, but the performance of the device may be enhanced if an organic light emitting material is used for a further emissive layer of the device. For example, a broader range of emission colours may be enabled and the colour gamut, electroluminescence efficiency and/or electroluminescence stability of the device may be enhanced. Combination of PeLED emissive layers with OLED emissive layers within a light emitting device may be particularly advantageous because organic light emitting materials with commercial performance may be complemented and enhanced by perovskite light emitting material performance.

In one embodiment, the first emissive layer 135 may comprise a perovskite light emitting material, and the second emissive layer 170 may comprise an organic light emitting material. This embodiment is depicted by light emitting device 605 in FIG. 14b.

In one embodiment, the first emissive layer 135 may comprise an organic light emitting material, and the second emissive layer 170 may comprise a perovskite light emitting material. This embodiment is depicted by light emitting device 615 in FIG. 14d.

In one embodiment, the at least one further emissive layer may comprises a perovskite light emitting material or a quantum dot light emitting material. This embodiment is depicted by light emitting devices 600 in FIG. 14a, 610 in FIGS. 14c and 620 in FIG. 14e.

In one embodiment, the first emissive layer 135 may comprise a perovskite light emitting material, and the second emissive layer 170 may comprise a perovskite light emitting material. This embodiment is depicted by light emitting device 600 in FIG. 14a. Such a device architecture may be advantageous in that the manufacturing process may be simplified for a light emitting device comprising only PeLED emissive layers.

In one embodiment, the at least one further emissive layer may comprise a quantum dot light emitting material. This embodiment is depicted by exemplary light emitting devices 610 in FIGS. 14c and 620 in FIG. 14e. Such device architectures may be advantageous because a perovskite light emitting material may be preferred for at least one emissive layer of a light emitting device, but the performance of the device may be enhanced if a quantum dot light emitting material is used for a further emissive layer of the device. For example, a broader range of emission colours may be enabled and the colour gamut, electroluminescence efficiency and/or electroluminescence stability of the device may be enhanced. Combination of PeLED emissive layers with QLED emissive layers within a light emitting device may be particularly advantageous because the similarity of structure of perovskite light-emitting materials and quantum dot light-emitting materials may allow these emissive layers to be manufactured together with little or no added complexity. For example, in the case of solution-process manufacturing, common solvents may be used to process perovskite light-emitting materials and quantum dot light-emitting materials.

In one embodiment, the first emissive layer 135 may comprise a perovskite light emitting material, and the second emissive layer 170 may comprise a quantum dot light emitting material. This embodiment is depicted by light emitting device 610 in FIG. 14c.

In one embodiment, the first emissive layer 135 may comprise a quantum dot light emitting material, and the second emissive layer 170 may comprise a perovskite light emitting material. This embodiment is depicted by light emitting device 620 in FIG. 14e.

In one embodiment, the light emitting device described with reference to FIGS. 13 and 14 may emit white light. In one embodiment, the light emitting device may emit white light having Duv less than or equal to 0.010. In one embodiment, the light emitting device may emit white light having Duv less than or equal to 0.005. Having a small Duv value may be of advantage in that the light emitting device may closely resemble a blackbody radiator.

In one embodiment, the light emitting device may be incorporated into a display. In one embodiment, the light emitting device may emit white light with CCT of approximately 6504K. Having a CCT of approximately 6504K may be of advantage in that the display may be easily calibrated to the illuminant D65 white point, which is the white point used for both DCI-P3 and Rec. 2020 standards.

In one embodiment, the light emitting device may be incorporated into a light panel. In one embodiment, the light emitting device may emit white light with CCT in the range of approximately 2700K to 6500K. In one embodiment, the light emitting device may emit light with CCT in the range of approximately 3000K to 5000K. Having a CCT in this range may be of advantage in that the light emitting device may appear a more natural colour and may meet the United States Department of Energy standard for Energy Star certification for Solid State Lighting. In one embodiment, the light emitting device may emit white light such that the CRI of the light emitting device is greater than or equal to 80. In one embodiment, the light emitting device may emit white light such that the CRI of the light emitting device is greater than or equal to 90. Having a high CRI may be of advantage in that the light emitting device may be able to render colours more accurately.

In one preferred embodiment, the light emitting device may emit white light and may comprise a yellow perovskite emissive layer, comprising perovskite light emitting material, and a blue organic emissive layer, comprising organic light emitting material.

In this embodiment, the device may benefit from the deep colour saturation of yellow perovskite light emitting material and blue organic light emitting material, thereby enabling displays with enhanced colour saturation and/or light panels with enhanced colour rendering performance.

In one embodiment, the light emitting device may emit yellow light. In one embodiment, the light emitting device may emit yellow light, and may comprise at least one red emissive layer and at least one green emissive layer. In one embodiment, the light emitting device may emit magenta light. In one embodiment, the light emitting device may emit magenta light, and may comprise at least one red emissive layer and at least one blue emissive layer. In one embodiment, the light emitting device may emit cyan light, and may comprise at least one green emissive layer and at least one blue emissive layer.

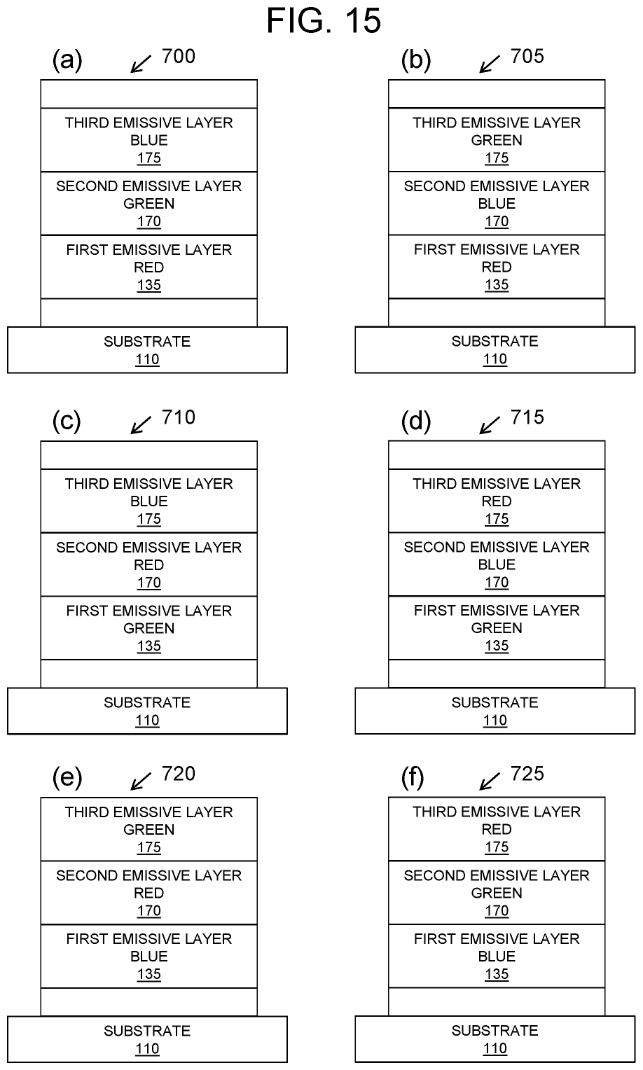

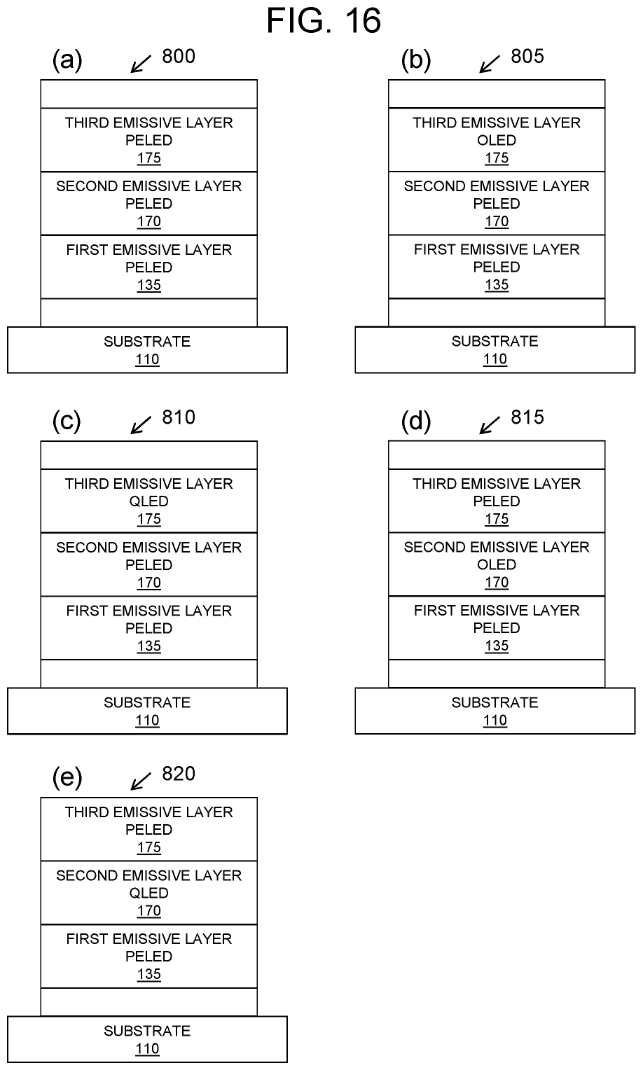

FIGS. 15 and 16 depict various configurations of emissive layers for a light emitting device having three emissive layers. In each configuration, the light emitting device comprises a substrate 110, a first emissive layer 135, a second emissive layer 170 and a third emissive layer 175. The first emissive layer 135 is disposed over the first electrode (not shown). The second emissive layer 170 is disposed over the first emissive layer 135. The third emissive layer 175 is disposed over the second emissive layer 170. The second electrode (not shown) is disposed over the third emissive layer 175. The first emissive layer 135 is in contact with the second emissive layer 170. The second emissive layer 170 is in contact with the third emissive layer 175. Various additional layers may be disposed between the first electrode and the first emissive layer 135. Various additional layers may be disposed between the third emissive layer 175 and the second electrode. In each configuration, the light emitting device comprises at least one emissive layer that comprises perovskite light emitting material. In each configuration, the light emitting device further comprises at least two further emissive layers that each comprise perovskite light emitting material, organic light emitting material or quantum dot light emitting material. Such a light emitting device architecture may be advantageous because the combination of different light emitting materials may enable the optimum type of light emitting material to be selected for each emissive layer, thereby enhancing performance beyond that which could be achieved by a light emitting device comprising only a single type of light emitting material, such as only perovskite light emitting material, only organic light emitting material or only quantum dot light emitting material. For example, a broader range of emission colours may be enabled and the colour gamut, electroluminescence efficiency and/or electroluminescence stability of the device may be enhanced.

FIG. 15 depicts various configurations of emissive layers that emit different colours of light for a light emitting device having three emissive layers.

In one embodiment, the first emissive layer 135 may comprise a red light emitting material, the second emissive layer 170 may comprise a green light emitting material and the third emissive layer 175 may comprise a blue light emitting material. This embodiment is depicted by light emitting device 700 in FIG. 15a.

In one embodiment, the first emissive layer 135 may comprise a red light emitting material, the second emissive layer 170 may comprise a blue light emitting material and the third emissive layer 175 may comprise a green light emitting material. This embodiment is depicted by light emitting device 705 in FIG. 15b.

In one embodiment, the first emissive layer 135 may comprise a green light emitting material, the second emissive layer 170 may comprise a red light emitting material and the third emissive layer 175 may comprise a blue light emitting material. This embodiment is depicted by light emitting device 710 in FIG. 15c.

In one embodiment, the first emissive layer 135 may comprise a green light emitting material, the second emissive layer 170 may comprise a blue light emitting material and the third emissive layer 175 may comprise a red light emitting material. This embodiment is depicted by light emitting device 715 in FIG. 15d.

In one embodiment, the first emissive layer 135 may comprise a blue light emitting material, the second emissive layer 170 may comprise a red light emitting material and the third emissive layer 175 may comprise a green light emitting material. This embodiment is depicted by light emitting device 720 in FIG. 15e.

In one embodiment, the first emissive layer 135 may comprise a blue light emitting material, the second emissive layer 170 may comprise a green light emitting material and the third emissive layer 175 may comprise a red light emitting material. This embodiment is depicted by light emitting device 725 in FIG. 15f.

FIG. 16 depicts various configurations of emissive layers comprising various different types of light emitting material for a light emitting device having three emissive layers. For simplicity, in FIG. 16, an emissive layer comprising perovskite light emitting material is labelled “PELED”, an emissive layer comprising organic light emitting material is labelled “OLED”, and an emissive layer comprising quantum dot light emitting material is labelled “QLED”.

In one embodiment, the first emissive layer 135 may comprise a perovskite light emitting material, the second emissive layer 170 may comprise a perovskite light emitting material, an organic light emitting material or a quantum dot light emitting material, and the third emissive layer 175 may comprise a perovskite light emitting material, an organic light emitting material or a quantum dot light emitting material.

In one embodiment, the first emissive layer 135 may comprise a perovskite light emitting material, an organic light emitting material or a quantum dot light emitting material, the second emissive layer 170 may comprise a perovskite light emitting material, and the third emissive layer 175 may comprise a perovskite light emitting material, an organic light emitting material or a quantum dot light emitting material.

In one embodiment, the first emissive layer 135 may comprise a perovskite light emitting material, an organic light emitting material or a quantum dot light emitting material, the second emissive layer 170 may comprise a perovskite light emitting material, an organic light emitting material or a quantum dot light emitting material, and the third emissive layer 175 may comprise a perovskite light emitting material.

In one embodiment, the at least two further emissive layers of the at least three emissive layers may each comprise a perovskite light emitting material or an organic light emitting material.

In one embodiment, the first emissive layer 135 may comprise a perovskite light emitting material, the second emissive layer 170 may comprise a perovskite light emitting material, and the third emissive layer 175 may comprise a perovskite light emitting material. This embodiment is depicted by light emitting device 800 in FIG. 16a. Such a device architecture may be advantageous in that the manufacturing process may be simplified for a light emitting device comprising only PeLED emissive layers.

In one embodiment, the at least two further emissive layers of the at least three emissive layers each comprise a perovskite light emitting material or an organic light emitting material, wherein at least one of the at least two further emissive layers comprises an organic light emitting material. Such device architectures may be advantageous because a perovskite light emitting material may be preferred for at least one emissive layer of a light emitting device, but the performance of the device may be enhanced if an organic light emitting material is used for at least one further emissive layer of the device. For example, a broader range of emission colours may be enables and the colour gamut, electroluminescence efficiency and/or electroluminescence stability of the device may be enhanced. Combination of PeLED emissive layers with OLED emissive layers within a light emitting device may be particularly advantageous because organic light emitting materials with commercial performance may be complemented and enhanced by perovskite light emitting material performance.

In one embodiment, the at least two further emissive layers of the at least three emissive layers each comprise a perovskite light emitting material or a quantum dot light emitting material.

In one embodiment, the at least two further emissive layers of the at least three emissive layers each comprise a perovskite light emitting material or a quantum dot light emitting material, wherein at least one of the at least two further emissive layers comprises quantum dot light emitting material. Such device architectures may be advantageous because a perovskite light emitting material may be preferred for at least one emissive layer of a light emitting device, but the performance of the device may be enhanced if a quantum dot light emitting material is used for at least one further emissive layer of the device. For example, a broader range of emission colours may be enabled and the colour gamut, electroluminescence efficiency and/or electroluminescence stability of the device may be enhanced. Combination of PeLED emissive layers with QLED emissive layers within a light emitting device may be particularly advantageous because the similarity of structure of perovskite light-emitting materials and quantum dot light-emitting materials may allow these emissive layers to be manufactured together with little or no added complexity. For example, in the case of solution-process manufacturing, common solvents may be used to process perovskite light-emitting materials and quantum dot light-emitting materials.

In one embodiment, the first emissive layer 135 may comprise a perovskite light emitting material, the second emissive layer 170 may comprise a perovskite light emitting material, and the third emissive layer 175 may comprise an organic light emitting material. This embodiment is depicted by light emitting device 805 in FIG. 16b.

In one embodiment, the first emissive layer 135 may comprise a perovskite light emitting material, the second emissive layer 170 may comprise a perovskite light emitting material, and the third emissive layer 175 may comprise a quantum dot light emitting material. This embodiment is depicted by light emitting device 810 in FIG. 16c.

In one embodiment, the first emissive layer 135 may comprise a perovskite light emitting material, the second emissive layer 170 may comprise an organic light emitting material, and the third emissive layer 175 may comprise a perovskite light emitting material. This embodiment is depicted by light emitting device 815 in FIG. 16d.

In one embodiment, the first emissive layer 135 may comprise a perovskite light emitting material, the second emissive layer 170 may comprise a quantum dot light emitting material, and the third emissive layer 175 may comprise a perovskite light emitting material. This embodiment is depicted by light emitting device 820 in FIG. 16e.

In one embodiment, the first emissive layer 135 may comprise an organic light emitting material, the second emissive layer 170 may comprise a perovskite light emitting material, and the third emissive layer 175 may comprise a perovskite light emitting material.

In one embodiment, the first emissive layer 135 may comprise a quantum dot light emitting material, the second emissive layer 170 may comprise a perovskite light emitting material, and the third emissive layer 175 may comprise a perovskite light emitting material.

In one embodiment, the first emissive layer 135 may comprise a perovskite light emitting material, the second emissive layer 170 may comprise an organic light emitting material, and the third emissive layer 175 may comprise an organic light emitting material.

In one embodiment, the first emissive layer 135 may comprise a perovskite light emitting material, the second emissive layer 170 may comprise an organic light emitting material, and the third emissive layer 175 may comprise a quantum dot light emitting material.

In one embodiment, the first emissive layer 135 may comprise a perovskite light emitting material, the second emissive layer 170 may comprise a quantum dot light emitting material, and the third emissive layer 175 may comprise an organic light emitting material.

In one embodiment, the first emissive layer 135 may comprise a perovskite light emitting material, the second emissive layer 170 may comprise a quantum dot light emitting material, and the third emissive layer 175 may comprise a quantum dot light emitting material.

In one embodiment, the first emissive layer 135 may comprise an organic light emitting material, the second emissive layer 170 may comprise a perovskite light emitting material, and the third emissive layer 175 may comprise an organic light emitting material.

In one embodiment, the first emissive layer 135 may comprise an organic light emitting material, the second emissive layer 170 may comprise a perovskite light emitting material, and the third emissive layer 175 may comprise a quantum dot light emitting material.

In one embodiment, the first emissive layer 135 may comprise a quantum dot light emitting material, the second emissive layer 170 may comprise a perovskite light emitting material, and the third emissive layer 175 may comprise an organic light emitting material.

In one embodiment, the first emissive layer 135 may comprise a quantum dot light emitting material, the second emissive layer 170 may comprise a perovskite light emitting material, and the third emissive layer 175 may comprise a quantum dot light emitting material.

In one embodiment, the first emissive layer 135 may comprise an organic light emitting material, the second emissive layer 170 may comprise an organic light emitting material, and the third emissive layer 175 may comprise a perovskite light emitting material.

In one embodiment, the first emissive layer 135 may comprise an organic light emitting material, the second emissive layer 170 may comprise a quantum dot light emitting material, and the third emissive layer 175 may comprise a perovskite light emitting material.

In one embodiment, the first emissive layer 135 may comprise a quantum dot light emitting material, the second emissive layer 170 may comprise an organic light emitting material, and the third emissive layer 175 may comprise a perovskite light emitting material.

In one embodiment, the first emissive layer 135 may comprise a quantum dot light emitting material, the second emissive layer 170 may comprise a quantum dot light emitting material, and the third emissive layer 175 may comprise a perovskite light emitting material.

In one embodiment, at least one emissive layer of the at least two further emissive layers comprises an organic light emitting material, and at least one emissive layer of the at least two further emissive layers comprises a quantum dot light emitting material. Such light emitting device architectures may be advantageous because the combination of different light emitting materials may enable the optimum type of light emitting material to be selected for each emissive layer, thereby enhancing performance beyond that which could be achieved by a light emitting device comprising only a single type of light emitting material, or only two types of light emitting material. For example, a broader range of emission colours may be enabled and the colour gamut, electroluminescence efficiency and/or electroluminescence stability of the device may be enhanced.

In one embodiment, the light emitting device described with reference to FIGS. 15 and 16 may emit white light. In one embodiment, the light emitting device may emit white light having Duv less than or equal to 0.010. In one embodiment, the light emitting device may emit white light having Duv less than or equal to 0.005. Having a small Duv value may be of advantage in that the light emitting device may closely resemble a blackbody radiator.

In one embodiment, the light emitting device may be incorporated into a display. In one embodiment, the light emitting device may emit white light with CCT of approximately 6504K. Having a CCT of approximately 6504K may be of advantage in that the display may be easily calibrated to the illuminant D65 white point, which is the white point used for both DCI-P3 and Rec. 2020 standards.

In one embodiment, the light emitting device may be incorporated into a light panel. In one embodiment, the light emitting device may emit white light with CCT in the range of approximately 2700K to 6500K. In one embodiment, the light emitting device may emit light with CCT in the range of approximately 3000K to 5000K. Having a CCT in this range may be of advantage in that the light emitting device may appear a more natural colour and may meet the United States Department of Energy standard for Energy Star certification for Solid State Lighting. In one embodiment, the light emitting device may emit white light such that the CRI of the light emitting device is greater than or equal to 80. In one embodiment, the light emitting device may emit white light such that the CRI of the light emitting device is greater than or equal to 90. Having a high CRI may be of advantage in that the light emitting device may be able to render colours more accurately.

In one preferred embodiment, the light emitting device may emit white light and may comprise a red perovskite emissive layer, comprising perovskite light emitting material, a green perovskite emissive layer, comprising perovskite light emitting material, and a blue organic emissive layer comprising organic light emitting material. In this embodiment, the device may benefit from the deep colour saturation of red and green perovskite light emitting material in combination with the deep colour saturation of blue organic light emitting material, thereby enabling displays with enhanced colour saturation and/or light panels with enhanced colour rendering performance.

In one embodiment, the light emitting device may be a stacked light emitting device. In one embodiment, the light emitting device may be a stacked light emitting device with two or more emissive units separated by one or more charge generation layers. In one embodiment, the light emitting device may be a stacked light emitting device with three or more emissive units separated by two or more charge generation layers. In one embodiment, at least one emissive unit of the stacked light emitting device may include multiple emissive layers.

Stacked light emitting device architectures may provide one or more of the following advantages: light from multiple emissive units may be combined within the same surface area of the device, thereby increasing the brightness of the device; multiple emissive units may be connected electrically in series, with substantially the same current passing through each emissive unit, thereby allowing the device to operate at increased brightness without substantial increase in current density, thereby extending the operation lifetime of the device; and the amount of light emitted from separate emissive units may be separately controlled, thereby allowing the brightness and/or colour of the device to be tuned according to the needs of the application. Connection of the emissive units in series further allows for direct current (DC) to flow through each emissive unit within the stacked light emitting device. This enables the stacked light emitting device to have a simple two electronic terminal design that is compatible with standard thin film transistor (TFT) backplane designs, such as passive matrix and active matrix backplanes used to drive electronic displays.

Optionally, one or more charge generation layers within a stacked light emitting device may or may not be directly connected to one or more external electrical sources, and therefore may or may not be individually addressable. Connecting one or more charge generation layers to one or more external sources may be of advantage in that light emission from separate emissive units may be separately controlled, allowing the brightness and/or colour of a stacked light emitting device with multiple emissive units to be tuned according to the needs of the application. Not connecting one or more of the charge generation layers to one or more external sources may be of advantage in that the stacked light emitting device may then be a two terminal electronic device that is compatible with standard thin film transistor (TFT) backplane designs, such as passive matrix and active matrix backplanes used to drive electronic displays.

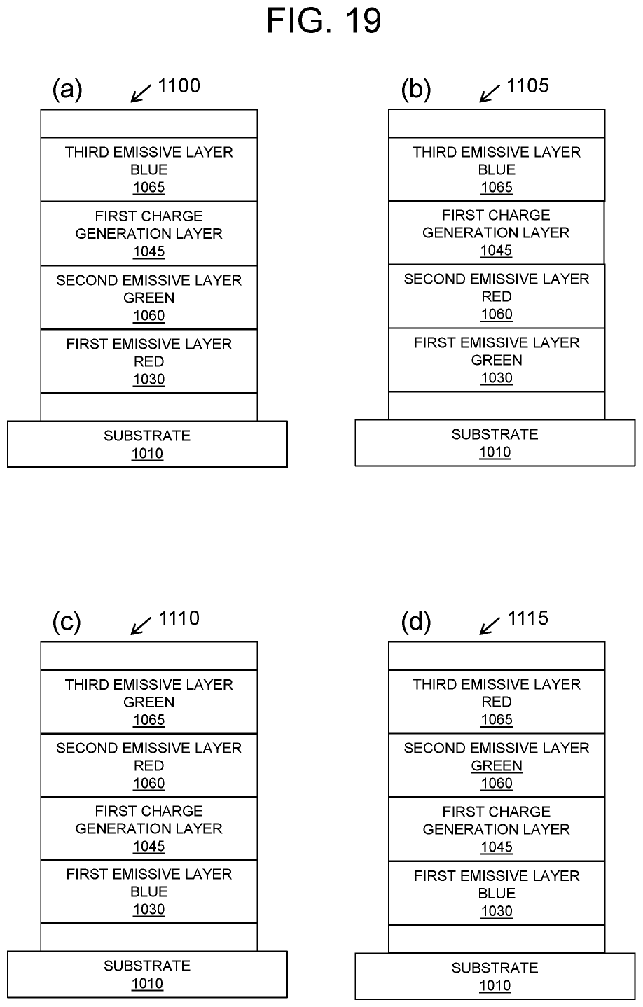

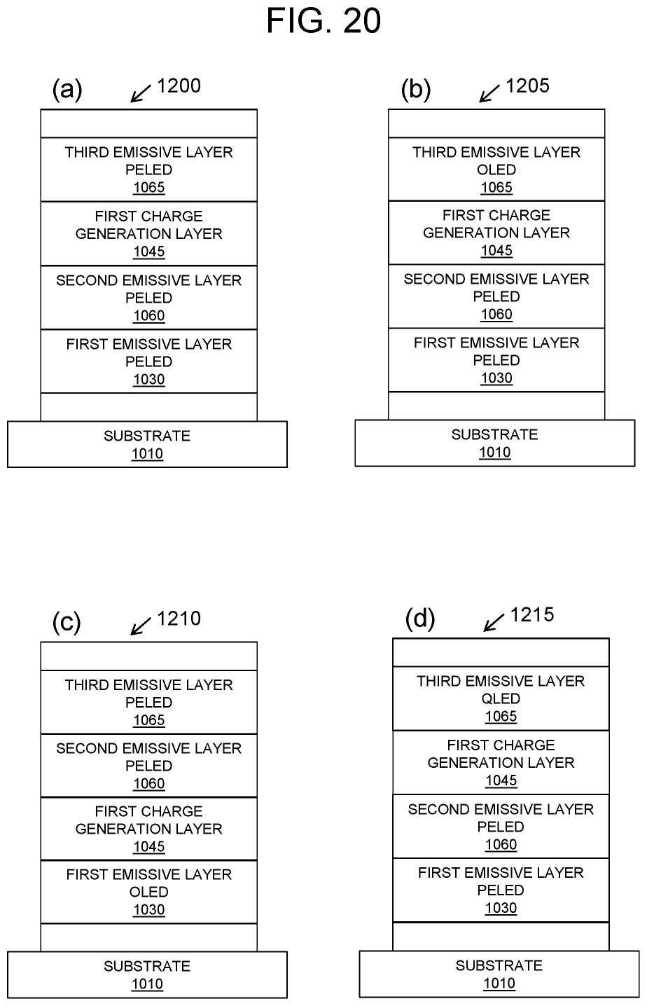

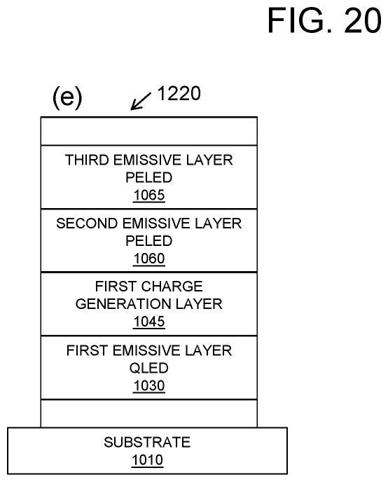

FIGS. 19 and 20 depict various configurations of emissive layers for a stacked light emitting device having three emissive layers. In each configuration, the stacked light emitting device comprises a substrate 1010, a first emissive layer 1030, a second emissive layer 1060, a third emissive layer 1065, and a first charge generation layer 1045. The first emissive layer 1030 is disposed over the first electrode (not shown). The second emissive layer 1060 is disposed over the first emissive layer 1030. The third emissive layer 1065 is disposed over the second emissive layer 1060. The second electrode (not shown) is disposed over the third emissive layer 1065. At least two of the at least three emissive layers are in contact with each other. The first charge generation layer 1045 is disposed between the first emissive layer 1030 and the third emissive layer 1066. Various additional layers may be disposed between the first electrode and the first emissive layer 1030. Various additional layers may be disposed between the third emissive layer 1065 and the second electrode. Various further additional layers may be included in the device. In each configuration, the light emitting device comprises at least one emissive layer that comprises perovskite light emitting material. In each configuration, the light emitting device further comprises at least two further emissive layer that each comprise perovskite light emitting material, organic light emitting material or quantum dot light emitting material.

FIG. 19 depicts various configurations of emissive layers that emit different colours of light for a stacked light emitting device having three emissive layers.

In one embodiment, the first emissive layer 1030 may comprise a red light emitting material, the second emissive layer 1060 may comprise a green light emitting material, and the third emissive layer 1065 may comprise a blue light emitting material. The first emissive layer 1030 may be in contact with the second emissive layer 1060. The first charge generation layer 1045 may be disposed between the second emissive layer 1060 and the third emissive layer 1065. This embodiment is depicted by light emitting device 1100 in FIG. 19a.

In one embodiment, the first emissive layer 1030 may comprise a green light emitting material, the second emissive layer 1060 may comprise a red light emitting material, and the third emissive layer 1065 may comprise a blue light emitting material. The first emissive layer 1030 may be in contact with the second emissive layer 1060. The first charge generation layer 1045 may be disposed between the second emissive layer 1060 and the third emissive layer 1065. This embodiment is depicted by light emitting device 1105 in FIG. 19b.

In one embodiment, the first emissive layer 1030 may comprise a blue light emitting material, the second emissive layer 1060 may comprise a red light emitting material, and the third emissive layer 1065 may comprise a green light emitting material. The first charge generation layer 1045 may be disposed between the first emissive layer 1030 and the second emissive layer 1060. The second emissive layer 1060 may be in contact with the third emissive layer 1065. This embodiment is depicted by light emitting device 1110 in FIG. 19c.

In one embodiment, the first emissive layer 1030 may comprise a blue light emitting material, the second emissive layer 1060 may comprise a green light emitting material, and the third emissive layer 1065 may comprise a red light emitting material. The first charge generation layer 1045 may be disposed between the first emissive layer 1030 and the second emissive layer 1060. The second emissive layer 1060 may be in contact with the third emissive layer 1065. This embodiment is depicted by light emitting device 1115 in FIG. 19d.

The examples shown in FIG. 19 and described in detail herein are shown by way of example and are non-limiting. Other combinations of colours and emissive layers are envisaged and included in this patent application.

FIG. 20 depicts various configurations of emissive layers comprising various different types of light emitting material for a stacked light emitting device having three emissive layers. For simplicity, in FIG. 20, an emissive layer comprising perovskite light emitting material is labelled “PELED”, an emissive layer comprising organic light emitting material is labelled “OLED”, and an emissive layer comprising quantum dot light emitting material is labelled “QLED”.

In one embodiment, the first emissive layer 1030 may comprise a perovskite light emitting material, the second emissive layer 1060 may comprise a perovskite light emitting material, an organic light emitting material or a quantum dot light emitting material, and the third emissive layer 1065 may comprise a perovskite light emitting material, an organic light emitting material or a quantum dot light emitting material. Optionally, the first emissive layer 1030 may be in contact with the second emissive layer 1060. Optionally, the first charge generation layer 1045 may be disposed between the second emissive layer 1060 and the third emissive layer 1065. Optionally, the second emissive layer 1060 may be in contact with the third emissive layer 1065. Optionally, the first charge generation layer 1045 may be disposed between the first emissive layer 1030 and the second emissive layer 1060.

In one embodiment, the first emissive layer 1030 may comprise a perovskite light emitting material, an organic light emitting material or a quantum dot light emitting material, the second emissive layer 1060 may comprise a perovskite light emitting material, and the third emissive layer 1065 may comprise a perovskite light emitting material, an organic light emitting material or a quantum dot light emitting material. Optionally, the first emissive layer 1030 may be in contact with the second emissive layer 1060. Optionally, the first charge generation layer 1045 may be disposed between the second emissive layer 1060 and the third emissive layer 1065. Optionally, the second emissive layer 1060 may be in contact with the third emissive layer 1065. Optionally, the first charge generation layer 1045 may be disposed between the first emissive layer 1030 and the second emissive layer 1060.

In one embodiment, the first emissive layer 1030 may comprise a perovskite light emitting material, an organic light emitting material or a quantum dot light emitting material, the second emissive layer 1060 may comprise a perovskite light emitting material, an organic light emitting material or a quantum dot light emitting material, and the third emissive layer 1065 may comprise a perovskite light emitting material. Optionally, the first emissive layer 1030 may be in contact with the second emissive layer 1060. Optionally, the first charge generation layer 1045 may be disposed between the second emissive layer 1060 and the third emissive layer 1065. Optionally, the second emissive layer 1060 may be in contact with the third emissive layer 1065. Optionally, the first charge generation layer 1045 may be disposed between the first emissive layer 1030 and the second emissive layer 1060.

In one embodiment, the first emissive layer 1030 may comprise a perovskite light emitting material, the second emissive layer 1060 may comprise a perovskite light emitting material, and the third emissive layer 1065 may comprise a perovskite light emitting material. The first emissive layer 1030 may be in contact with the second emissive layer 1060. The first charge generation layer 1045 may be disposed between the second emissive layer 1060 and the third emissive layer 1065. This embodiment is depicted by light emitting device 1200 in FIG. 20a.

In one embodiment, the first emissive layer 1030 may comprise a perovskite light emitting material, the second emissive layer 1060 may comprise a perovskite light emitting material, and the third emissive layer 1065 may comprise an organic light emitting material. The first emissive layer 1030 may be in contact with the second emissive layer 1060. The first charge generation layer 1045 may be disposed between the second emissive layer 1060 and the third emissive layer 1065. This embodiment is depicted by light emitting device 1205 in FIG. 20b.

In one embodiment, the first emissive layer 1030 may comprise an organic light emitting material, the second emissive layer 1060 may comprise a perovskite light emitting material, and the third emissive layer 1065 may comprise a perovskite light emitting material. The first charge generation layer 1045 may be disposed between the first emissive layer 1030 and the second emissive layer 1060. The second emissive layer 1060 may be in contact with the third emissive layer 1065. This embodiment is depicted by light emitting device 1210 in FIG. 20c.

In one embodiment, the first emissive layer 1030 may comprise a perovskite light emitting material, the second emissive layer 1060 may comprise a perovskite light emitting material, and the third emissive layer 1065 may comprise an quantum dot light emitting material. The first emissive layer 1030 may be in contact with the second emissive layer 1060. The first charge generation layer 1045 may be disposed between the second emissive layer 1060 and the third emissive layer 1065. This embodiment is depicted by light emitting device 1215 in FIG. 20d.

In one embodiment, the first emissive layer 1030 may comprise a quantum dot light emitting material, the second emissive layer 1060 may comprise a perovskite light emitting material, and the third emissive layer 1065 may comprise a perovskite light emitting material. The first charge generation layer 1045 may be disposed between the first emissive layer 1030 and the second emissive layer 1060. The second emissive layer 1060 may be in contact with the third emissive layer 1065. This embodiment is depicted by light emitting device 1220 in FIG. 20e.

The examples shown in FIG. 20 and described in detail herein are shown by way of example and are non-limiting. Other combinations of light emitting material types and emissive layers are envisaged and included in this patent application.

In one embodiment, the stacked light emitting device described with reference to FIGS. 19 and 20 may emit white light. In one embodiment, the stacked light emitting device may emit white light having Duv less than or equal to 0.010. In one embodiment, the stacked light emitting device may emit white light having Duv less than or equal to 0.005. Having a small Duv value may be of advantage in that the light emitting device may closely resemble a blackbody radiator.

In one embodiment, the stacked light emitting device may be incorporated into a display. In one embodiment, the light emitting device may emit white light with CCT of approximately 6504K. Having a CCT of approximately 6504K may be of advantage in that the display may be easily calibrated to the illuminant D65 white point, which is the white point used for both DCI-P3 and Rec. 2020 standards.

In one embodiment, the stacked light emitting device may be incorporated into a light panel. In one embodiment, the stacked light emitting device may emit white light with CCT in the range of approximately 2700K to 6500K. In one embodiment, the stacked light emitting device may emit light with CCT in the range of approximately 3000K to 5000K. Having a CCT in this range may be of advantage in that the light emitting device may appear a more natural colour and may meet the United States Department of Energy standard for Energy Star certification for Solid State Lighting. In one embodiment, the stacked light emitting device may emit white light such that the CRI of the light emitting device is greater than or equal to 80. In one embodiment, the stacked light emitting device may emit white light such that the CRI of the light emitting device is greater than or equal to 90. Having a high CRI may be of advantage in that the light emitting device may be able to render colours more accurately.

In one preferred embodiment, the stacked light emitting device may emit white light and may comprise at least one emissive unit comprising a red perovskite emissive layer, comprising perovskite light emitting material, in contact with a green perovskite emissive layer, comprising perovskite light emitting material, and at least one further emissive unit comprising a blue organic emissive layer comprising organic light emitting material. In this embodiment, the device may benefit from deep colour saturation of red and green perovskite light emitting material in combination with the deep colour saturation of blue organic light emitting material, thereby enabling displays with enhanced colour saturation and/or light panels with enhanced colour rendering performance.

In one embodiment, the light emitting device described with reference to FIGS. 13, 14, 15, 16, 19 and 20 may be incorporated into a sub-pixel of a display. In one embodiment, the sub-pixel of the display may emit white light with CCT of approximately 6504K. Having a CCT of approximately 6504K may be of advantage in that the display may be easily calibrated to the illuminant D65 white point, which is the white point used for both DCI-P3 and Rec. 2020 standards. Optionally, the display may be incorporated into a wide range of consumer products. Optionally, the display may be used in televisions, computer monitors, tablets, laptop computers, smart phones, cell phones, digital cameras, video recorders, smartwatches, fitness trackers, personal digital assistants, vehicle displays and other electronic devices. Optionally, the display may be used for micro-displays or heads-up displays. Optionally, the display may be used in light sources for interior or exterior illumination and/or signaling, in smart packaging or in billboards.

In one embodiment, the light emitting device described with reference to FIGS. 13, 14, 15, 16, 19 and 20 may be included in a light panel. Optionally, the light panel may be included in a wide range of consumer products. Optionally the light panel may be used for interior or exterior illumination and/or signaling, in smart packaging or in billboards.

In one embodiment, the light emitting device described with reference to FIGS. 13, 14, 15, 16, 19 and 20 may include a microcavity structure. Optionally, as described herein, a microcavity structure may be created where a transparent and partially reflective electrode is used in combination with an opposing reflective electrode. Optionally, in a standard device architecture, a bottom-emission microcavity structure may be created using a transparent and partially reflective multilayer anode such as ITO/Ag/ITO, where the Ag thickness is less than approximately 25 nm, in combination with a reflective multilayer cathode such as LiF/Al. In this architecture, light emission is through the anode. Optionally, in a standard device architecture, a top-emission microcavity structure may be created using a transparent and partially reflective compound cathode such as Mg:Ag in combination with a reflective multilayer anode such as ITO/Ag/ITO, where the Ag thickness is greater than approximately 80 nm. In this architecture, light emission is through the cathode.

Such a device may be of advantage in that such a microcavity structure may increase the total amount of light emitted from the device, thereby increasing the efficiency and brightness of the device. Such a device may further be of advantage in that such a microcavity structure may increase the proportion of light emitted in the forward direction from the device, thereby increasing the apparent brightness of the device to a user positioned at normal incidence. Such a device may further be of advantage in that such a microcavity structure may narrow the spectrum of emitted light from the device, thereby increasing the colour saturation of the emitted light. Application of such a microcavity structure to the device may thereby enable the device to render a primary colour of the DCI-P3 colour gamut. Application of such a microcavity structure to the device may thereby enable the device to render a primary colour of the Rec. 2020 colour gamut. For example, this may be achieved by applying such a microcavity structure to a light emitting device as disclosed herein comprising yellow and blue, or red, green and blue emissive layers, respectively.

In one embodiment, the light emitting device described with reference to FIGS. 13, 14, 15, 16, 19 and 20 may include one or more colour altering layers. As described herein, there are in general two classes of colour altering layers: colour filters that modify a spectrum by removing unwanted wavelengths of light, and colour changing layers that convert photons of higher energy to photons of lower energy. Optionally, the one or more colour altering layers may comprise one or more colour filters. Optionally, the one or more colour altering layers may comprise one or more colour changing layers.

Such a device may be of advantage in that the inclusion of one or more colour altering layers may alter the spectrum of emitted light from one or more sub-pixels to which they are applied, thereby increasing the colour saturation of the emitted light and optionally the colour gamut of a display into which the device may be incorporated. Optionally, application of one or more colour altering layers may thereby enable the display to render the DCI-P3 colour gamut. Optionally, application of one or more colour altering layers may thereby enable the display to render the Rec. 2020 colour gamut. For example, this may be achieved by applying one or more colour altering layers to a light emitting device as disclosed herein comprising yellow and blue, or red, green and blue emissive layers, respectively.

A person skilled in the art will understand that only a few examples of use are described, but that they are in no way limiting.

Modifications to embodiments of the invention described in the foregoing are possible without departing from the scope of the invention as defined by the accompanying claims. Expressions such as “including”, “comprising”, “incorporating”, “consisting of”, “have”, “is” used to describe and claim the present invention are intended to be construed in a non-exclusive manner, namely allowing for items, components or elements not explicitly described also to be present. Reference to the singular is also to be construed to relate to the plural. Any numerals included within parentheses in the accompanying claims are intended to assist understanding of the claims and should not be construed in any way to limit subject matter claimed by these claims.

### PATENT REFERENCES

EP 0423283 B1, Friend et al., Electroluminescent Devices

U.S. Pat. No. 6,303,238 B1, Thompson et al., OLEDs Doped with Phosphorescent Compounds

U.S. Pat. No. 7,279,704 B2, Walters et al., Complexes with Tridentate Ligands

U.S. Pat. No. 8,654,001 B2, Hack et al., Organic Light Emitting Device Lighting Panel

### OTHER REFERENCES

Adamovich et al., All-phosphorescent white stacked organic LEDs for solid-state lighting, SPIE Newsroom, 10.1117/2.1201110.003846 (2011).

Adjokatse et al., Broadly tunable metal halide perovskites for solid-state light-emission applications, Materials Today, Volume 20, Issue 8, Pages 413-424 (2017).

Andrade et al., White Organic Light-Emitting Devices for Solid-State Lighting, Advanced Materials, Volume 16, Pages 1585-1595 (2004).

Hirose et al., High-efficiency Perovskite QLED Achieving BT.2020 Green Chromaticity, SID Symposium Digest of Technical Papers 2017, Volume 48, Pages 284-287 (2017).

Kathirgamanathan et al. (1), Electroluminescent Organic and Quantum Dot LEDs: The State of the Art, Journal of Display Technology, Volume 11, Number 5, Pages 480-493 (2015).

Kathirgamanathan et al. (2), Quantum Dot Electroluminescence: Towards Achieving the REC 2020 Colour Co-ordinates, SID Symposium Digest of Technical Papers 2015, Volume 47, Pages 652-656 (2016).

Kumar et al., Efficient Blue Electroluminescence Using Quantum-Confined Two-Dimensional Perovskites, ACS Nano, Volume 10, Pages 9720-9729 (2016).

Soneira et al., iPhone X OLED Display Technology Shoot-Out, DisplayMate Technologies Corporation, http://www.displaymate.com/iPhoneX_ShootOut_1a.htm [accessed 20 May, 2018].

Takita et al., Highly efficient deep-blue fluorescent dopant for achieving low-power OLED display satisfying BT.2020 chromaticity, Journal of the SID 2018 (2018).

Uoyama et al., Highly efficient organic light-emitting diodes from delayed fluorescence, Nature, Volume 492, Pages 234-238 (2012).

Wang et al., Perovskite light-emitting diodes based on solution-processed, self-organised multiple quantum wells, Nature Photonics, Volume 10, Pages 699-704 (2016).

1. A light emitting device comprising:
a first electrode;
a second electrode; and
at least two emissive layers;
wherein a first emissive layer of the at least two emissive layers is disposed over the first electrode;
wherein a second emissive layer of the at least two emissive layers is disposed over the first emissive layer;
wherein the second electrode is disposed over the second emissive layer;
wherein the first emissive layer is in contact with the second emissive layer;
wherein at least one emissive layer of the at least two emissive layers comprises a perovskite light emitting material;
wherein the device comprises at least one further emissive layer of the at least two emissive layers; and
wherein the at least one further emissive layer comprises a perovskite light emitting material, an organic light emitting material or a quantum dot light emitting material.

2. The device of claim 1, wherein the first emissive layer comprises a perovskite light emitting material, and the second emissive layer comprises a perovskite light emitting material, an organic light emitting material or a quantum dot light emitting material.

3. The device of claim 1, wherein the first emissive layer comprises a perovskite light emitting material, an organic light emitting material or a quantum dot light emitting material, and the second emissive layer comprises a perovskite light emitting material.

4. The device of any one of claims 1 to 3, wherein the at least one further emissive layer of the at least two emissive layers comprises a perovskite light emitting material or an organic light emitting material.

5. The device of claim 4, wherein the first emissive layer comprises a perovskite light emitting material, and the second emissive layer comprises a perovskite light emitting material.

6. The device of claim 4, wherein the at least one further emissive layer of the at least two emissive layers comprises an organic light emitting material.

7. The device of claim 6, wherein the first emissive layer comprises a perovskite light emitting material, and the second emissive layer comprises an organic light emitting material.

8. The device of claim 6, wherein the first emissive layer comprises an organic light emitting material, and the second emissive layer comprises a perovskite light emitting material.

9. The device of any one of claims 1 to 3, wherein the at least one further emissive layer of the at least two emissive layers comprises a perovskite light emitting material or a quantum dot light emitting material.

10. The device of claim 9, wherein the first emissive layer comprises a perovskite light emitting material, and the second emissive layer comprises a perovskite light emitting material.

11. The device of claim 9, wherein the at least one further emissive layer of the at least two emissive layers comprises a quantum dot light emitting material.

12. The device of claim 11, wherein the first emissive layer comprises a perovskite light emitting material, and the second emissive layer comprises a quantum dot light emitting material.

13. The device of claim 11, wherein the first emissive layer comprises a quantum dot light emitting material, and the second emissive layer comprises a perovskite light emitting material.

14. The device of any one of the previous claims, wherein one or more of the emissive layers comprise organic metal halide light-emitting perovskite material.

15. The device of any one of the previous claims, wherein one or more of the emissive layers comprise inorganic metal halide light-emitting perovskite material.

16. The device of any one of claims 1 to 15, wherein at least one emissive layer of the at least two emissive layers emits yellow light, and at least one further emissive layer of the at least two emissive layers emits blue light.

17. The device of claim 16, wherein the device emits white light.

18. The device of claim 17, wherein the device emits white light with colour rendering index greater than or equal to 80.

19. The devices of claim 17, wherein the device emits white light with a correlated colour temperature of approximately 6504K.

20. The device of any one of claims 1 to 15, wherein at least one emissive layer of the at least two emissive layers emits red light, and at least one further emissive layer of the at least two emissive layers emits green light.

21. The device of claim 20, wherein the device emits yellow light.

22. A light emitting device comprising:
a first electrode;
a second electrode; and
at least three emissive layers;
wherein a first emissive layer of the at least three emissive layers is disposed over the first electrode;
wherein a second emissive layer of the at least three emissive layers is disposed over the first emissive layer;
wherein a third emissive layer of the at least three emissive layers is disposed over the second emissive layer;
wherein the second electrode is disposed over the third emissive layer;
wherein the first emissive layer is in contact with the second emissive layer;
wherein the second emissive layer is in contact with the third emissive layer;
wherein at least one emissive layer of the at least three emissive layers comprises a perovskite light emitting material; and
wherein the device comprises at least two further emissive layers of the at least three emissive layers; and
wherein each of the at least two further emissive layers comprises a perovskite light emitting material, an organic light emitting material or a quantum dot light emitting material.

23. The device of claim 22, wherein the at least two further emissive layers of the at least three emissive layers each comprise a perovskite light emitting material or an organic light emitting material.

24. The device of claim 23, wherein the first emissive layer comprises a perovskite light emitting material, the second emissive layer comprises a perovskite light emitting material, and the third emissive layer comprises a perovskite light emitting material.

25. The device of claim 23, wherein at least one emissive layer of the at least two further emissive layers comprises an organic light emitting material.

26. The device of claim 22, wherein the at least two further emissive layers of the at least three emissive layers each comprise a perovskite light emitting material or a quantum dot emitting material.

27. The device of claim 26, wherein the first emissive layer comprises a perovskite light emitting material, the second emissive layer comprises a perovskite light emitting material, and the third emissive layer comprises a perovskite light emitting material.

28. The device of claim 26, wherein at least one emissive layer of the at least two further emissive layers comprises a quantum dot light emitting material.

29. The device of claim 22, wherein at least one emissive layer of the at least two further emissive layers comprises an organic light emitting material, and at least one emissive layer of the at least two further emissive layers comprises a quantum dot light emitting material.

30. The device of any one of claims 22 to 29, wherein at least one emissive layer of the at least three emissive layers emits red light, at least one further emissive layer of the at least three emissive layers emits green light, and at least one further emissive layer of the at least three emissive layers emits blue light.

31. The device of claim 30, wherein the device emits white light.

32. The device of claim 31, wherein the device emits white light with colour rendering index greater than or equal to 80.

33. The device of claim 31, wherein the device emits white light with a correlated colour temperature of approximately 6504K.

34. The device of any one of claims 1 to 33, wherein the device is a stacked light emitting device.

35. A stacked light emitting device comprising:
a first electrode;
a second electrode;
a first emissive unit;
a second emissive unit;
a charge generation layer; and
at least three emissive layers;
wherein a first emissive layer of the at least three emissive layers is disposed over the first electrode;
wherein a second emissive layer of the at least three emissive layers is disposed over the first emissive layer;
wherein a third emissive layer of the at least three emissive layers is disposed over the second emissive layer;
wherein the second electrode is disposed over the third emissive layer;
wherein the first emissive unit comprises the first emissive layer and the second emissive layer;
wherein the second emissive unit comprises the third emissive layer;
wherein the charge generation layer is disposed between the second emissive layer and the third emissive layer;
wherein the first emissive layer is in contact with the second emissive layer;
wherein at least one emissive layer of the at least three emissive layers comprises a perovskite light emitting material; and
wherein the device comprises at least two further emissive layers of the at least three emissive layers; and
wherein each of the at least two further emissive layers comprises a perovskite light emitting material, an organic light emitting material or a quantum dot light emitting material.

36. The device of claim 35, wherein at least one of the first emissive layer and the second emissive layer emits red light, at least one of the first emissive layer and the second emissive layer emits green light, and the third emissive layer emits blue light.

37. A stacked light emitting device comprising:
a first electrode;
a second electrode;
a first emissive unit;
a second emissive unit;
a charge generation layer; and
at least three emissive layers;
wherein a first emissive layer of the at least three emissive layers is disposed over the first electrode;
wherein a second emissive layer of the at least three emissive layers is disposed over the first emissive layer;
wherein a third emissive layer of the at least three emissive layers is disposed over the second emissive layer;
wherein the second electrode is disposed over the third emissive layer;
wherein the first emissive unit comprises the first emissive layer;
wherein the second emissive unit comprises the second emissive layer and the third emissive layer;
wherein the charge generation layer is disposed between the first emissive layer and the second emissive layer;
wherein the second emissive layer is in contact with the third emissive layer;
wherein at least one emissive layer of the at least three emissive layers comprises a perovskite light emitting material; and
wherein the device comprises at least two further emissive layers of the at least three emissive layers; and
wherein each of the at least two further emissive layers comprises a perovskite light emitting material, an organic light emitting material or a quantum dot light emitting material.

38. The device of claim 37, wherein the first emissive layer emits blue light, at least one of the second emissive layer and the third emissive layer emits red light, and at least one of the second emissive layer and the third emissive layer emits green light.

39. The device of any one of claims 35 to 38, wherein the device emits white light.

40. The device of claim 39, wherein the device emits white light with colour rendering index greater than or equal to 80.

41. The device of claim 39, wherein the device emits white light with a correlated colour temperature of approximately 6504K.

42. The device of any one of the previous claims, wherein the device further includes a microcavity structure.

43. The device of any one of the previous claims, wherein the device further includes a colour altering layer.

44. A sub-pixel of a display comprising the device of any one of claims 1 to 43.

45. A light panel comprising the device of any one of claims 1 to 43.
